(19) United States
(12) Patent Application Publication
(10) Pub. No.: US 2026/0123212 A1
(43) Pub. Date: Apr. 30, 2026

(54) DISPLAY DEVICE INCLUDING POWER LINES AND ELECTRONIC DEVICE INCLUDING THE SAME

(71) Applicant: SAMSUNG DISPLAY CO., LTD., YONGIN-SI (KR)

(72) Inventors: Jisun Kim, YONGIN-SI (KR); Sunmi Kang, YONGIN-SI (KR); Kwihyun Kim, YONGIN-SI (KR); Heejean Park, YONGIN-SI (KR); Sehyun Lee, YONGIN-SI (KR); Kyunghoon Chung, YONGIN-SI (KR)

(21) Appl. No.: 19/275,329

(22) Filed: Jul. 21, 2025

(30) Foreign Application Priority Data
Oct. 31, 2024 (KR) 10-2024-0152962

(51) Int. Cl. H10K 59/131

(52) U.S. Cl. CPC H10K 59/131

(57) ABSTRACT

A display device includes a first thin-film transistor, a second thin-film transistor, and a third thin-film transistor. The first thin-film transistor includes a first semiconductor pattern, the second thin-film transistor includes a second semiconductor pattern, and the third thin-film transistor includes a third semiconductor pattern. A first power line is disposed on the first semiconductor pattern to apply a first power voltage, a second power line is disposed on the second semiconductor pattern to apply a second power voltage, and a third power line is disposed on the third semiconductor pattern to apply a third power voltage. A first, second, and third lower power lines are disposed below the first, second, and third semiconductor patterns, respectively. The first power voltage and the second power voltage are each different from the third power voltage. At least one of the lower power lines is electrically connected to a corresponding power line.

### CROSS-REFERENCE TO RELATED APPLICATION

This application claims priority under 35 U.S.C. § 119 to Korean Patent Application No. 10-2024-0152962, filed on Oct. 31, 2024, in the Korean Intellectual Property Office, the disclosure of which is incorporated by reference herein in its entirety.

### 1. Technical Field

The present disclosure relates to a display device and, more specifically, to a display device including power lines and an electronic device including the same.

### 2. Discussion of the Related Art

Display devices may visually display data. The display devices may have pixels as display elements. A single pixel may include a plurality of subpixels. The subpixels may include light-emitting elements and subpixel circuits connected to the light-emitting elements to drive the light-emitting elements. The light-emitting elements may include light-emitting diodes, for example, organic light-emitting diodes. The subpixel circuits may include one or more thin-film transistors and various wirings.

### SUMMARY

According to embodiments of the disclosure, a display device includes a first subpixel circuit including a first thin-film transistor. The first thin-film transistor includes a first semiconductor pattern. A display device includes a second subpixel circuit including a second thin-film transistor. The second thin-film transistor includes a second semiconductor pattern. A display device includes a third subpixel circuit including a third thin-film transistor. The third thin-film transistor includes a third semiconductor pattern. A display device includes a first power line disposed on the first semiconductor pattern, the first power line is configured to apply a first power voltage to the first subpixel circuit. A display device includes a second power line disposed on the second semiconductor pattern, the second power line is configured to apply a second power voltage to the second subpixel circuit. A display device includes a third power line disposed on the third semiconductor pattern, the third power line is configured to apply a third power voltage to the third subpixel circuit. A display device includes a first lower power line disposed below the first semiconductor pattern. A display device includes a second lower power line disposed below the second semiconductor pattern. A display device includes a third lower power line disposed below the third semiconductor pattern. A value of the first power voltage and a value of the second power voltage are each different from a value of the third power voltage. At least one of the first lower power line, the second lower power line, and the third lower power line is electrically connected to a corresponding power line among the first power line, the second power line, and the third power line.

In embodiments, the first power line and the second power line may be electrically connected to each other and may be separated from the third power line.

In embodiments, the first lower power line and the second lower power line may be electrically connected to each other and may be separated from the third lower power line.

In embodiments, the first lower power line or the second lower power line may be electrically connected to a corresponding power line among the first power line and the second power line, and any one of the first lower power line and the second lower power line may be separated from the corresponding power line among the first power line and the second power line.

In embodiments, the display device may include a display area including the first subpixel circuit, the second subpixel circuit, and the third subpixel circuit. The display device may include a peripheral area proximate to the display area. The first lower power line and the second lower power line may each extend to the peripheral area.

In embodiments, the first lower power line and the second lower power line may be electrically connected to a power voltage line disposed in the peripheral area, the first lower power line and the second lower power line may be configured to receive the first power voltage or the second power voltage. The third lower power line may be electrically connected to the third power line, and the third lower power line may be configured to receive the third power voltage.

In embodiments, the first lower power line and the second lower power line may be integrally formed with one another. The first lower power line and the second lower power line together may have a mesh structure.

In embodiments, the third lower power line may have an island shape disposed in an opening of the mesh structure.

In embodiments, the island shape of the third lower power line may include protrusions extending toward the first lower power line or the second lower power line.

In embodiments, the value of the first power voltage may be equal to the value of the second power voltage.

According to embodiments of the disclosure, a display device includes a first subpixel including a first semiconductor pattern, a first power line disposed on the first semiconductor pattern, and a first lower power line disposed below the first semiconductor pattern. A display device includes a second subpixel including a second semiconductor pattern, a second power line disposed on the second semiconductor pattern, and a second lower power line disposed below the second semiconductor pattern. A display device includes a third subpixel including a third semiconductor pattern, a third power line disposed on the third semiconductor pattern, and a third lower power line disposed below the third semiconductor pattern. The third lower power line is separated from both the first lower power line and the second lower power line and is electrically connected to the third power line.

In embodiments, the first lower power line and the second lower power line may be electrically connected to each other.

In embodiments, the first lower power line and the second lower power line may be electrically connected to at least one of the first power line and the second power line.

In embodiments, a display device may include a display area including the first subpixel, the second subpixel, and the third subpixel. The display device may include a peripheral area proximate to the display area. The first lower power line and the second lower power line may each extend to the peripheral area.

In embodiments, the first lower power line and the second lower power line may be electrically connected to a power voltage line disposed in the peripheral area.

In embodiments, the first lower power line and the second lower power line may be integrally formed with one another. The first lower power line and the second lower power line together may have a mesh structure.

In embodiments, the third lower power line may have an island shape disposed in an opening of the mesh structure.

In embodiments, the island shape of the third lower power line may include protrusions extending toward the first lower power line or the second lower power line.

In embodiments, a first power voltage may be applied to the first power line, a second power voltage having an equal value as the first power voltage may be applied to the second power line, and a third power voltage having a different value from the first power voltage may be applied to the third power line.

According to embodiments of the disclosure, an electronic device includes a housing, and a display device disposed inside the housing. The display device includes a first subpixel circuit including a first thin-film transistor. The first thin-film transistor includes a first semiconductor pattern. The display device includes a second subpixel circuit including a second thin-film transistor. The second thin-film transistor includes a second semiconductor pattern. The display device includes a third subpixel circuit including a third thin-film transistor. The third thin-film transistor includes a third semiconductor pattern. The display device includes a first power line disposed on the first semiconductor pattern, the first power line is configured to apply a first power voltage to the first subpixel circuit. The display device includes a second power line disposed on the second semiconductor pattern, the second power line is configured to apply a second power voltage to the second subpixel circuit. The display device includes a third power line disposed on the third semiconductor pattern, the third power line is configured to apply a third power voltage to the third subpixel circuit. The display device includes a first lower power line disposed below the first semiconductor pattern. The display device includes a second lower power line disposed below the second semiconductor pattern. The display device includes a third lower power line disposed below the third semiconductor pattern. A value of the first power voltage and a value of the second power voltage are each different from a value of the third power voltage. At least one of the first lower power line, the second lower power line, and the third lower power line is electrically connected to a corresponding power line among the first power line, the second power line, and the third power line.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a schematic plan view of an electronic device according to an embodiment of the present disclosure;

FIG. 2A is a schematic plan view of a portion of a display device according to an embodiment of the present disclosure;

FIG. 2B is a schematic plan view of a portion of the display device according to an embodiment of the present disclosure;

FIG. 2C is a schematic plan view of a portion of the display device according to an embodiment of the present disclosure;

FIG. 3A is an equivalent circuit diagram of a first subpixel according to an embodiment of the present disclosure;

FIG. 3B is an equivalent circuit diagram of a second subpixel according to an embodiment of the present disclosure;

FIG. 3C is an equivalent circuit diagram of a third subpixel according to an embodiment of the present disclosure;

FIG. 4A is a cross-sectional view of the display device according to an embodiment of the present disclosure;

FIG. 4B is a cross-sectional view of the display device according to an embodiment of the present disclosure;

FIG. 5 is a cross-sectional view of the display device according to an embodiment of the present disclosure;

FIG. 6 is a cross-sectional view of the display device according to an embodiment of the present disclosure;

FIG. 7 is a cross-sectional view of the display device according to an embodiment of the present disclosure;

FIG. 8 is a cross-sectional view of the display device according to an embodiment of the present disclosure;

FIG. 9 is a cross-sectional view of the display device according to an embodiment of the present disclosure;

FIG. 10 is a plan view of a portion of the display device according to an embodiment of the present disclosure;

FIG. 11 is a plan view of a portion of the display device according to an embodiment of the present disclosure;

FIG. 12 is a plan view of a portion of the display device according to an embodiment of the present disclosure; and

FIG. 13 is a plan view of a portion of the display device according to an embodiment of the present disclosure.

### DETAILED DESCRIPTION OF THE EMBODIMENTS

The present invention will now be described more fully hereinafter with reference to the accompanying drawings, in which embodiments of the invention are shown. Like reference numerals refer to like elements throughout the specification and the drawings. This invention may, however, be embodied in different forms and should not necessarily be construed as limited to the embodiments set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b, or c” may indicate only a, only b, only c, both a and b, both a and c, both b and c, all of a, b, and c, or variations thereof.

Effects and characteristics of the disclosure, and a method of accomplishing these will be apparent when referring to embodiments described with reference to the drawings. Embodiments are provided so that this disclosure will be thorough and complete, and will fully convey the scope of the invention to those skilled in the art.

Although the terms “first”, “second”, etc. may be used herein to describe various elements, these elements, should not necessarily be limited by these terms. These terms may be used to distinguish one element from another element. Thus, a first element discussed below may be termed a second element without departing from the teachings of one or more embodiments. The description of an element as a “first” element might not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

The terminology used herein is for the purpose of describing example embodiments only and is not necessarily intended to be limiting of the present inventive concept. As used herein, the singular expressions “a,” “an,” and “the” may be intended to include the plural forms as well, unless the context clearly indicates otherwise.

The terms “comprises” and/or “comprising”, when used herein, specify the presence of stated features, integers, steps, operations, elements, and/or components, but do not necessarily preclude the presence or addition of one or more other features, integers, steps, operations, elements, components, and/or groups thereof.

As used herein, when a layer, area, or element is referred to as being formed “on” another layer, area, or element, it can be directly or indirectly formed on the other layer, area, or element. For example, intervening layers, areas, or elements may be present.

Spatially relative terms such as “below”, “at the bottom”, “lower”, “below”, “above”, “on top”, “on the top”, “on”, etc., are used to explain a relationship between components shown in the drawings. The terms are relative concepts and are explained based on the direction indicated in the drawings. Spatially relative terms are intended to include other directions in use, in operation, and/or in manufacturing, in addition to the direction depicted in the drawings. For example, in case that a device shown in the drawing is turned upside down, elements depicted as being positioned “under” other elements or features are positioned in a direction “on” the other elements or features. Therefore, in an embodiment, the term “under”may include both directions of “on”and “under”.

While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like. In some embodiments, since sizes and thicknesses of elements in the drawings may be arbitrarily illustrated for convenience of description, the following embodiments are not necessarily limited thereto.

When a certain embodiment may be implemented differently, a specific process order may be performed differently from the described order. For example, two consecutively described processes may be performed substantially at the same time or performed in an order opposite to the described order.

Embodiments of the present disclosure are described with the understanding that when an element, an area, or a layer is referred to as being connected to another element, area, or layer, it can be directly and/or indirectly connected to the other element, area, or layer. For example, in the present disclosure, when an element, an area, or a layer is referred to as being electrically connected to another element, area, or layer, it can be directly and electrically connected to another element, area, or layer, or may be indirectly and electrically connected to another element, area, or layer with the other element, area, or layer therebetween.

Traditionally, a display device may include light-emitting elements and subpixels. However, the color of light emitted from the light-emitting elements may vary for each subpixel, thus requiring different power voltages for each subpixel.

To resolve these challenges, a device including thin-film transistors is provided. The thin-film transistors may include semiconductor patterns. Power lines may be disposed above and/or below the semiconductor patterns. Power lines may be configured to supply the required level of power voltages to each subpixel.

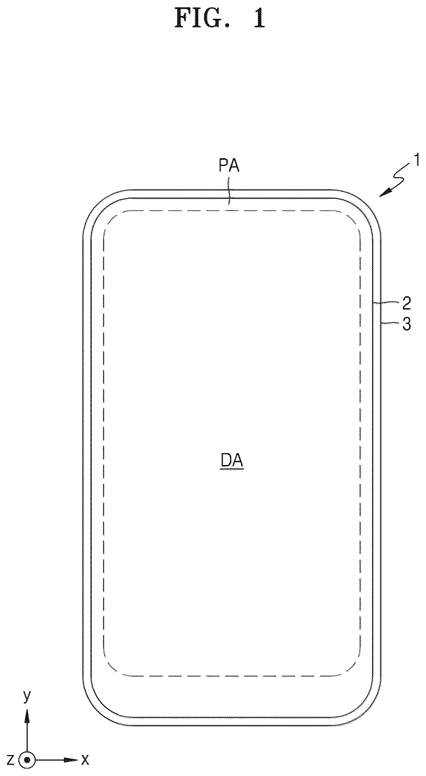

FIG. 1 is a schematic plan view of an electronic device 1 according to an embodiment.

The electronic device 1 may include a display device 2 and a housing 3. In an embodiment, the display device 2 may be accommodated in the housing 3.

In an embodiment, the electronic device 1 may include portable electronic devices such as mobile phones, smartphones, tablet computers, mobile communication terminals, electronic notebooks, electronic books, portable multimedia players (PMP), navigation devices, ultra-mobile PCs (UMPC), etc. In an embodiment, the electronic device 1 may include various products such as televisions, laptop/notebook computers, computer monitors, digital billboards, and internet of things (IOT) devices. In an embodiment, the display device 1 may include wearable devices, such as smart watches, watch phones, eyewear displays, and head-mounted displays (HMD). In an embodiment, the display device 1 may include display devices for vehicles, such as a dashboard of a vehicle, a center information display (CID) arranged in a center fascia or dashboard of a vehicle, a room mirror display replacing the side mirror of a vehicle, and a display device arranged on the rear surface of the front seat for entertainment of the back seat passenger of a vehicle. The display device 2 may be included in the electronic device 1 as a component that displays a moving image or still image in various embodiments of the electronic device 1 described herein.

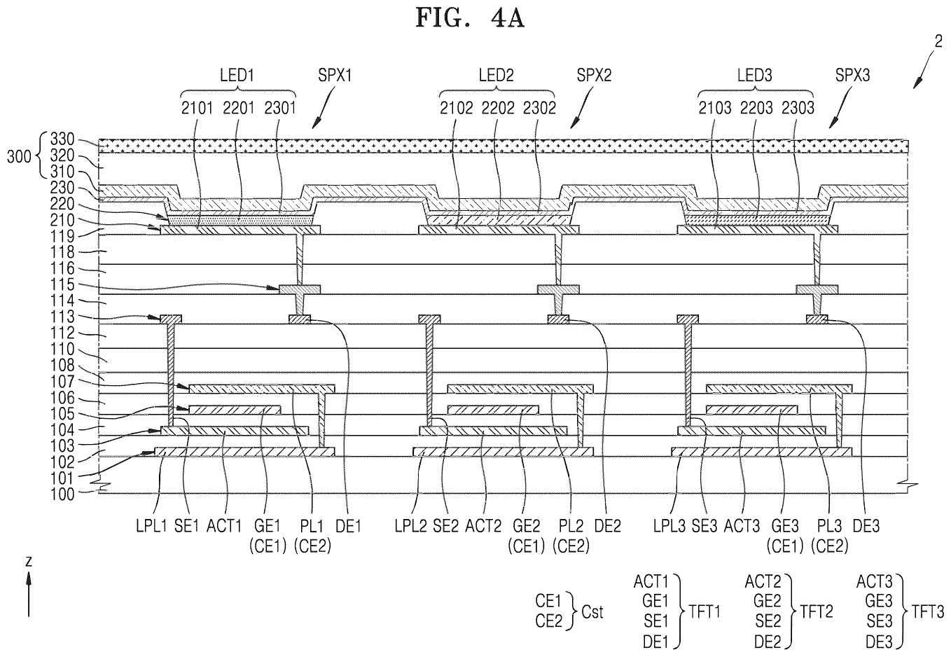

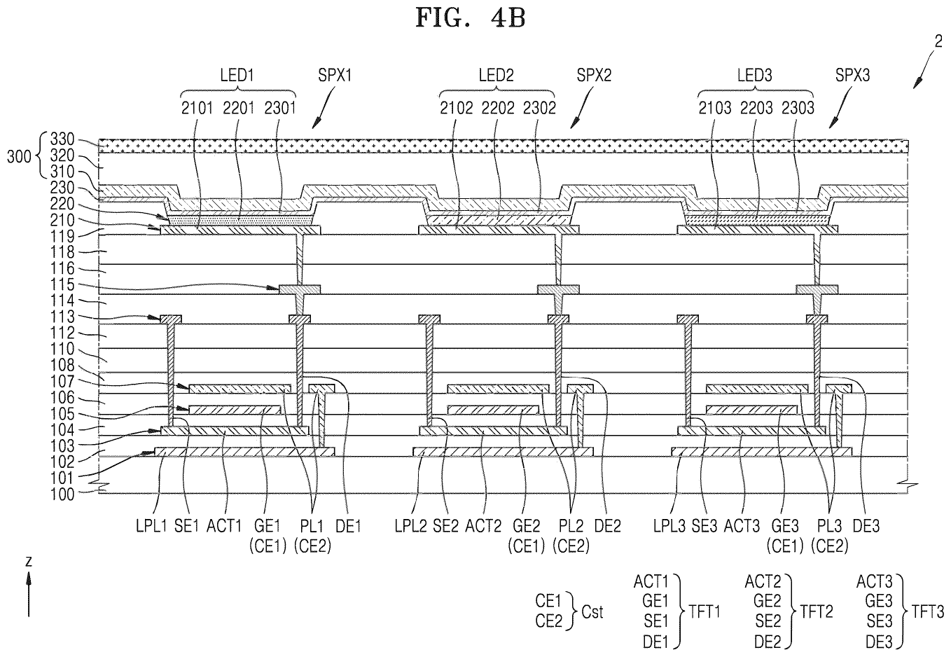

The display device 2 may include a display area DA and a peripheral area PA outside (or, on the periphery of) the display area DA. In an embodiment, the peripheral area PA maybe proximate to the display area DA. In an embodiment, since the display device 2 includes a substrate 100 (refer to FIG. 4A), the substrate 100 may include the display area DA and the peripheral area PA. In some embodiments, the display area DA and the peripheral area PA may be defined on the substrate 100.

In embodiments, the display area DA may be a portion for displaying an image. A plurality of pixels PX may be disposed in the display area DA. The display area DA may have various shapes, such as a circular shape, an oval shape, a polygonal shape, a shape of a specific figure, and the like. As an example, FIG. 1 illustrates that the display area DA has a substantially rectangular shape with round corners.

The peripheral area PA may be arranged outside the display area DA. The peripheral area PA may surround at least a portion of the display area DA. For example, the peripheral area PA may be proximate to at least one side of the display area DA.

In embodiments, an organic light-emitting display device is described as an example of the display device 2, however, the display device disclosed herein is not necessarily limited thereto. In some embodiments, the display device 2 of the disclosure may be a display device such as an inorganic light-emitting display or a quantum dot light-emitting display. For example, an emission layer of a display element included in the display device may include an organic material, an inorganic material, and quantum dots. For example, an emission layer of a display element included in the display device may include an organic material and quantum dots. For example, an emission layer of a display element included in the display device may include an inorganic material and quantum dots.

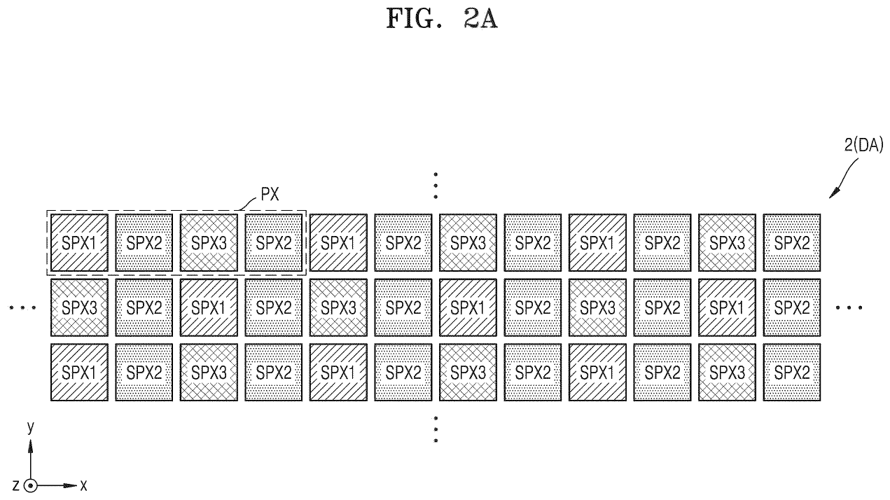

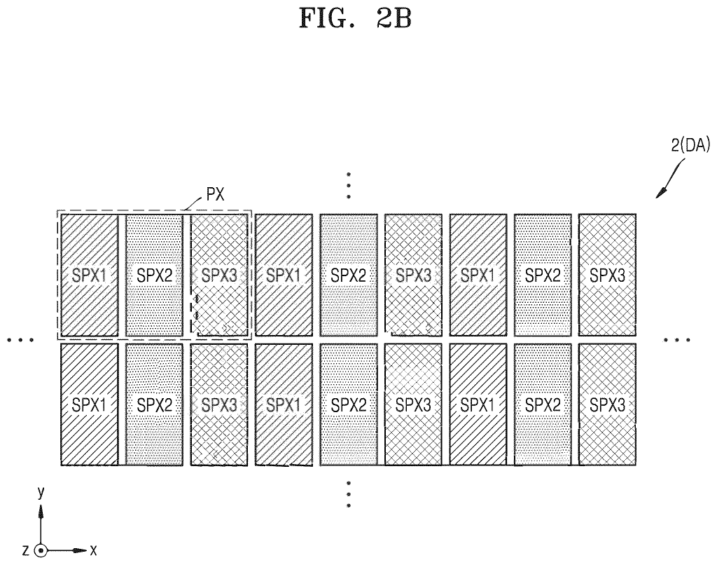

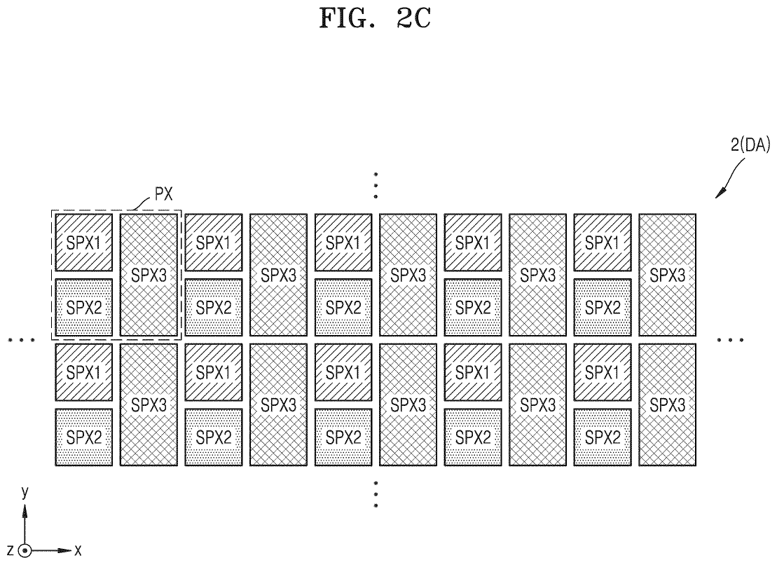

FIGS. 2A to 2C are schematic plan views of a portion of the display device 2 according to some embodiments.

Referring to FIGS. 2A to 2C, the display device 2 may include a plurality of pixels PX as display elements. Each of the plurality of pixels PX may emit light of a specific color, and accordingly, the display device 2 may display an image. A pixel PX may include a plurality of subpixels SPX1, SPX2, and SPX3 (hereinafter, also referred to as a first subpixel SPX1, a second subpixel SPX2, and a third subpixel SPX3). For example, a pixel PX may include a first subpixel SPX1, a second subpixel SPX2, and a third subpixel SPX3.

In an embodiment, the first subpixel SPX1 may emit red light. In an embodiment, the second subpixel SPX2 may emit green light. In an embodiment, the third subpixel SPX3 may emit blue light. In an embodiment, the intensity of light emitted by each of the first subpixel SPX1, the second subpixel SPX2, and the third subpixel SPX3 may be different. By combining light emitted from the first subpixel SPX1, the second subpixel SPX2, and the third subpixel SPX3, the pixel PX may emit light of various colors.

Referring to FIG. 2A, a pixel PX may include one first sub-pixel SPX1, two second sub-pixels SPX2, and one third sub-pixel SPX3. In an embodiment, the subpixels SPX1, SPX2, and SPX3 of each pixel PX may be arranged in the order of the first subpixel SPX1, the second subpixel SPX2, the third subpixel SPX3, and the second subpixel SPX2 in a first direction (e.g., an x direction). In an embodiment, first subpixels SPX1 and third subpixels SPX3 included in different pixels PX may be arranged alternately in a second direction (e.g., a y direction). In an embodiment, second subpixels SPX2 included in different pixels PX may be arranged in the second direction (e.g., the y direction). In an embodiment, the shape and/or size of the first subpixel SPX1, the second subpixel SPX2, and the third subpixel SPX3 may be the same.

Referring to FIG. 2B, a pixel PX may include one first subpixel SPX1, two second subpixels SPX2, and one third subpixel SPX3. In an embodiment, the subpixels SPX1, SPX2, and SPX3 of each pixel PX may be arranged in the order of the first subpixel SPX1, the second subpixel SPX2, and the third subpixel SPX3 in the first direction (e.g., the x direction). In an embodiment, the first subpixels SPX1 included in different pixels PX may be arranged in the second direction (e.g., the y direction). In an embodiment, the second subpixels SPX2 included in different pixels PX may be arranged in the second direction (e.g., the y direction). In an embodiment, the first subpixels SPX1 included in different pixels PX may be arranged in the third direction (e.g., the z direction). In an embodiment, the shape and/or size of the first subpixel SPX1, the second subpixel SPX2, and the third subpixel SPX3 may be the same.

Referring to FIG. 2C, a pixel PX may include one first subpixel SPX1, one second subpixel SPX2, and one third subpixel SPX3. In an embodiment, the first subpixel SPX1 and the second subpixel SPX2 of each pixel PX may be arranged in the second direction (e.g., the y direction), and the third subpixel SPX3 of each pixel PX may be arranged in the first direction (e.g., the x direction). In an embodiment, the first subpixels SPX1 and the second subpixels SPX2 included in different pixels PX may be arranged alternately in the second direction (e.g., the y direction). In an embodiment, the third subpixels SPX3 included in different pixels PX may be arranged in the second direction (e.g., the y direction). In an embodiment, the first subpixel SPX1 and the second subpixel SPX2 may be identical to each other in shape and/or size. In an embodiment, the shape and/or size of the third subpixel SPX3 may be different from the shapes and/or sizes of the first subpixel SPX1 and the second subpixel SPX2. For example, as illustrated in FIG. 2C, the size of the third subpixel SPX3 may be greater than the sizes of the first subpixel SPX1 and the second subpixel SPX2.

The embodiments described with reference to FIGS. 2A to 2C are example embodiments, and the disclosure is not necessarily limited to the pixel PX and the subpixels SPX1, SPX2, and SPX3 described herein. The number, type, size, and arrangement of the subpixels SPX1, SPX2, and SPX3 included in a pixel PX may vary.

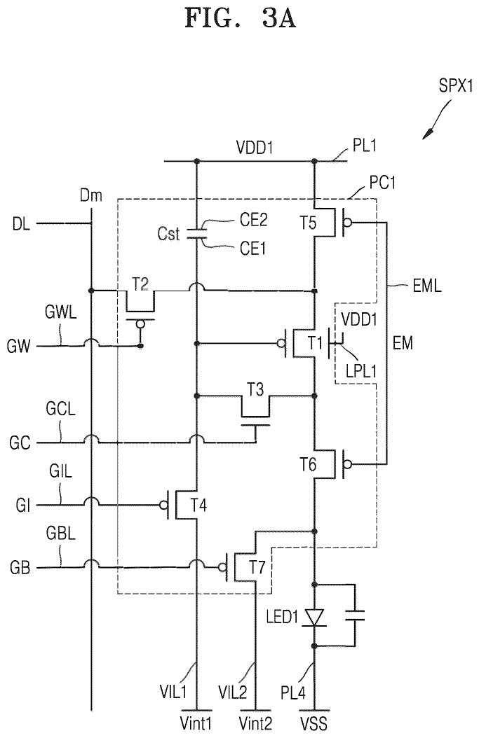

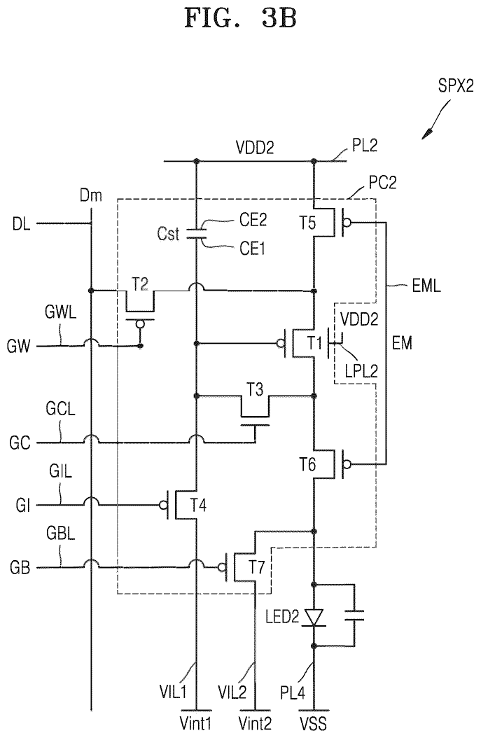

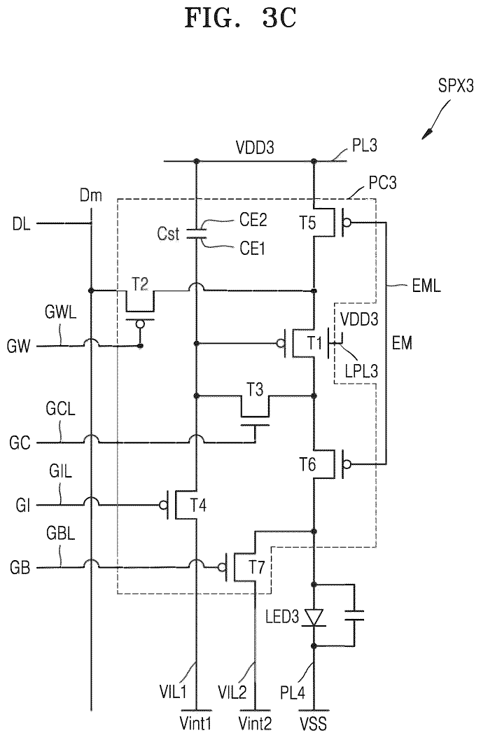

FIG. 3A is an equivalent circuit diagram of the first subpixel SPX1 according to an embodiment. FIG. 3B is an equivalent circuit diagram of the second subpixel SPX2 according to an embodiment. FIG. 3C is an equivalent circuit diagram of the third subpixel SPX3 according to an embodiment.

Referring to FIG. 3A, the first subpixel SPX1 may include a first subpixel circuit PC1 and a first light-emitting diode LED1. The first subpixel circuit PC1 and the first light-emitting diode LED1 may be connected to each other. For example, the first subpixel circuit PC1 and the first light-emitting diode LED1 may be electrically connected to each other. The first light-emitting diode LED1 may be a light-emitting element of the first subpixel SPX1 and may emit light of a specific color. In an embodiment, the first light-emitting diode LED1 may emit red light. The first subpixel circuit PC1 may drive the first light-emitting diode LED1.

The first subpixel circuit PC1 may include a first transistor T1, a second transistor T2, a third transistor T3, a fourth transistor T4, a fifth transistor T5, a sixth transistor T6, a seventh transistor T7, and a storage capacitor Cst. The first subpixel circuit PC1 may be electrically connected to a data line DL, a first initialization voltage line VIL1, a second initialization voltage line VIL2, a first scan line GWL, a second scan line GCL, a third scan line GIL, a fourth scan line GBL, an emission control line EML, a first power line PL1, and a first lower power line LPL1. In embodiments, the first subpixel circuit PC1 may be electrically connected to a plurality of signal lines.

The data line DL may transmit a data signal Dm to the first subpixel circuit PC1. The first initialization voltage line VIL1 may transmit a first initialization voltage Vint1 that initializes the first transistor T1 to the first subpixel circuit PC1. The second initialization voltage line VIL2 may transmit a second initialization voltage Vint2 that initializes the first light-emitting diode LED1 to the first subpixel circuit PC1. The first scan line GWL may transmit a first scan signal GW to the first subpixel circuit PC1. The second scan line GCL may transmit a second scan signal GC to the first subpixel circuit PC1. The third scan line GIL may transmit a third scan signal GI to the first subpixel circuit PC1. The fourth scan line GBL may transmit a fourth scan signal GB to the first subpixel circuit PC1. An emission control line EML may transmit an emission control signal EM to the first subpixel circuit PC1. The first power line PL1 may transmit a first power voltage VDD1 to the first subpixel circuit PC1. The first lower power line LPL1 may transmit a first power voltage VDD1 to the first transistor T1 of the first subpixel circuit PC1.

The first transistor T1 may be electrically connected to the first power line PL1 via the fifth transistor T5 and may be electrically connected to the first light-emitting diode LED1 via the sixth transistor T6. The first transistor T1 may receive the data signal Dm according to a switching operation of the second transistor T2 and may supply a driving current to the first light-emitting diode LED1. In an embodiment, the first transistor T1 may be a driving transistor.

The second transistor T2 may be electrically connected to the data line DL and may be electrically connected to the first power line PL1 via the fifth transistor T5. A gate of the second transistor T2 may be electrically connected to the first scan line GWL. The second transistor T2 may be turned on according to the first scan signal GW received through the first scan line GWL and may perform a switching operation of transmitting the data signal Dm received from the data line DL to a node between the first transistor T1 and the fifth transistor T5. In an embodiment, the second transistor T2 may be a switching transistor.

The third transistor T3 may be electrically connected to the first transistor T1. A gate of the third transistor T3 may be electrically connected to the second scan line GCL. The third transistor T3 may be turned on in response to the second scan signal GC received through the second scan line GCL and may diode-connect the first transistor T1. In an embodiment, the third transistor T3 may be a compensation transistor.

The fourth transistor T4 may be electrically connected to the first initialization voltage line VIL1. A gate of the fourth transistor T4 may be electrically connected to the third scan line GIL. The fourth transistor T4 may be turned on in response to the third scan signal GI received through the third scan line GIL and transmit the first initialization voltage Vint1 received from the first initialization voltage line VIL1 to a gate of the first transistor T1 to initialize the voltage of the gate of the first transistor T1. In an embodiment, the fourth transistor T4 may be a first initialization transistor.

Gates of each of the fifth transistor T5 and the sixth transistor T6 may be electrically connected to the emission control line EML. The fifth transistor T5 and the sixth transistor T6 may be turned on simultaneously in response to the emission control signal EM received through the emission control line EML and may thereby form a current path such that the driving current may flow from the first power line PL1 toward the first light-emitting diode LED1. In an embodiment, the fifth transistor T5 may be an operation control transistor, and the sixth transistor T6 may be an emission control transistor.

The seventh transistor T7 may be electrically connected to the second initialization voltage line VIL2 and the first light-emitting diode LED1. A gate of the seventh transistor T7 may be electrically connected to the fourth scan line GBL. The seventh transistor T7 may be turned on according to the fourth scan signal GB received through the fourth scan line GBL and may transmit the second initialization voltage Vint2 received from the second initialization voltage line VIL2 to the first light-emitting diode LED1 to initialize the first light-emitting diode LED1. In an embodiment, the seventh transistor T7 may be a second initialization transistor.

The storage capacitor Cst may include a first capacitor electrode CE1 and a second capacitor electrode CE2. The first capacitor electrode CE1 may be electrically connected to the gate of the first transistor T1, and the second capacitor electrode CE2 may be electrically connected to the first power line PL1. The storage capacitor Cst may store and maintain a voltage corresponding to a difference between voltages across the first power line PL1 and the gate electrode of the first transistor T1, to maintain the voltage applied to the gate of the first transistor T1.

The first light-emitting diode LED1 may include a first subpixel electrode (2101) and a first counter electrode (2301) (refer to FIG. 4A). The first subpixel electrode 2101 may receive the first power voltage VDD1 via the fifth transistor T5, the first transistor T1, and the sixth transistor T6. The first counter electrode 2301 may be connected to a fourth power line PL4 and may receive a common power voltage VSS. The first light-emitting diode LED1 may emit light by receiving a current, for example, a driving current, caused by a potential difference between the first power voltage VDD1 and the common power voltage VSS.

In describing the second subpixel SPX2 and the third subpixel SPX3 with reference to FIGS. 3B and 3C, features that are substantially the same as the features of the first subpixel SPX1 with reference to FIG. 3A are omitted and differences are mainly described. To the extent that an element is not described in detail with respect to a figure, it may be understood that the element is at least similar to a corresponding element that has been described elsewhere within the present disclosure.

Referring to FIG. 3B, the second subpixel SPX2 may include a second subpixel circuit PC2 and a second light-emitting diode LED2. The second subpixel SPX2 and the second light-emitting diode LED2 may be electrically connected to each other. The second light-emitting diode LED2 may be a light-emitting element of the second subpixel SPX2 and may emit light of a specific color. In an embodiment, the second light-emitting diode LED2 may emit green light.

The second subpixel circuit PC2 may be electrically connected to a second power line PL2 and a second lower power line LPL2. The second power line PL2 may transmit a second power voltage VDD2 to the second subpixel circuit PC2. The second lower power line LPL2 may transmit a second power voltage VDD2 to the first transistor T1 of the second subpixel circuit PC2.

The second light-emitting diode LED2 may include a second subpixel electrode 2102 and a second counter electrode 2302 (refer to FIG. 4A). The second subpixel electrode 2102 may receive the second power voltage VDD2 via the fifth transistor T5, the first transistor T1, and the sixth transistor T6. A second counter electrode 2302 may be connected to the fourth power line PL4 and may receive the common power voltage VSS. The second light-emitting diode LED2 may emit light by receiving a current, for example, a driving current, caused by a potential difference between the second power voltage VDD2 and the common power voltage VSS.

Referring to FIG. 3C, the third subpixel SPX3 may include a third subpixel circuit PC3 and a third light-emitting diode LED3. The third subpixel SPX3 and the third light-emitting diode LED3 may be electrically connected to each other. The third light-emitting diode LED3 is a light-emitting element of the third subpixel SPX3 and may emit light of a specific color. In an embodiment, the third light-emitting diode LED3 may emit blue light.

The third subpixel circuit PC3 may be electrically connected to a third power line PL3 and a third lower power line LPL3. The third power line PL3 may transmit a third power voltage VDD3 to the third subpixel circuit PC3. The third lower power line LPL3 may transmit a third power voltage VDD3 to the first transistor T1 of the third subpixel circuit PC3.

The third light-emitting diode LED3 may include a third subpixel electrode 2103 and a third counter electrode 2303 (refer to FIG. 4A). The third subpixel electrode 2103 may receive the third power voltage VDD3 via the fifth transistor T5, the first transistor T1, and the sixth transistor T6. A third counter electrode 2303 may be electrically connected to the fourth power line PL4 and may receive the common power voltage VSS. The third light-emitting diode LED3 may emit light by receiving a current, for example, a driving current, caused by a potential difference between the second power voltage VDD2 and the common power voltage VSS.

In embodiments, referring to FIGS. 3A to 3C together, the first to third subpixels SPX1, SPX2, and SPX3 may have different power lines, lower power lines, power voltages, and light-emitting diodes corresponding thereto. For example, the first subpixel circuit PC1 of the first subpixel SPX1 may be connected to the first power line PL1, the first lower power line LPL1, and the first light-emitting diode LED1. The first power line PL1 and the first lower power line LPL1 may transmit the first power voltage VDD1 to the first subpixel circuit PC1. In embodiments, the second subpixel circuit PC2 of the second subpixel SPX2 may be connected to the second power line PL2, the second lower power line LPL2, and the second light-emitting diode LED2. The second power line PL2 and the second lower power line LPL2 may transmit the second power voltage VDD2 to the second subpixel circuit PC2. In embodiments, the third subpixel circuit PC3 of the third subpixel SPX3 may be connected to the third power line PL3, the third lower power line LPL3, and the third light-emitting diode LED3. The third power line PL3 and the third lower power line LPL3 may deliver the third power voltage VDD3 to the third subpixel circuit PC3.

In an embodiment, the first power voltage VDD1 may be the same as the second power voltage VDD2. For example, a value of the first power voltage VDD1 may be equal to a value of the second power voltage VDD2. In an embodiment, the first power voltage VDD1 and the second power voltage VDD2 may be different from the third power voltage VDD3. For example, a value of the first power voltage VDD1 and a value of the second power voltage VDD2 may be different from a value of the third power voltage VDD3. In an embodiment, the first power line PL1 and the second power line PL2 may be connected to each other. In an embodiment, the first power line PL1 and the second power line PL2 may be separated from the third power line PL3. In an embodiment, the first lower power line LPL1 and the second lower power line PL2 may be connected to each other. In an embodiment, the first lower power line LPL1 and the second lower power line LPL2 may be separated from the third lower power line LPL3. In an embodiment, the first light-emitting diode LED1, the second light-emitting diode LED2, and the third light-emitting diode LED3 may emit light of different colors.

The fourth power line PL4 and the common power voltage VSS may be common to the first to third subpixels SPX1, SPX2, and SPX3. For example, the first to third light-emitting diodes LED1, LED2, and LED3 may commonly be connected to the fourth power line PL4 and may receive the same common power voltage VSS.

FIG. 4A is a cross-sectional view of the display device 2 according to an embodiment. FIG. 4B is a cross-sectional view of the display device 2 according to an embodiment. FIGS. 4A and 4B may be cross-sectional views of different portions of an embodiment of display devices 2.

Referring to FIGS. 4A and 4B, the first subpixel SPX1, the second subpixel SPX2, and the third subpixel SPX3 may be arranged on the substrate 100.

The first subpixel SPX1 may include the first light-emitting diode LED1 as a light-emitting element and a first thin-film transistor TFT1 connected to the first light-emitting diode LED1. In an embodiment, the first thin-film transistor TFT1 may be the first transistor T1 of the first subpixel circuit PC1 described with reference to FIG. 3A.

The second subpixel SPX2 may include the second light-emitting diode LED2 as a light-emitting element and a second thin-film transistor TFT2 connected to the second light-emitting diode LED2. In an embodiment, the second thin-film transistor TFT2 may be the first transistor T1 of the second subpixel circuit PC2 described with reference to FIG. 3B.

The third subpixel SPX3 may include the third light-emitting diode LED3 as a light-emitting element and a third thin-film transistor TFT3 connected to the third light-emitting diode LED3. In an embodiment, the third thin-film transistor TFT3 may be the first transistor T1 of the third subpixel circuit PC3 described with reference to FIG. 3C.

The substrate 100 may include glass materials or polymer resins. In an embodiment, the substrate 100 may include a structure in which base layers including a polymer resin, and barrier layers including an inorganic insulating material are alternately stacked. The polymer resin may include at least one of polyether sulfone, polyacrylate, polyether imide, polyethylene naphthalate, polyethylene terephthalate, polyphenylene sulfide, polyimide, polycarbonate, cellulose triacetate, cellulose acetate propionate, and the like. The inorganic insulating material may include one or more materials such as silicon oxide (SiO₂) or silicon nitride (SiNₓ).

A first conductive layer 101 may be disposed on the substrate 100. The first conductive layer 101 may include the first lower power line LPL1, the second lower power line LPL2, and the third lower power line LPL3. In an embodiment, the first lower power line LPL1, the second lower power line LPL2, and the third lower power line LPL3 may be individually patterned. In an embodiment, the first lower power line LPL1 and the second lower power line LPL2 may be connected to each other. In an embodiment, the first lower power line LPL1 and the third lower power line LPL3 may be separated from each other. In an embodiment, the second lower power line LPL2 and the third lower power line LPL3 may be separated from each other.

The first insulating layer 102 may be disposed on the first conductive layer 101. The first insulating layer 102 may cover the entire first conductive layer 101. For example, the first insulating layer 102 may entirely cover the first lower power line LPL1, the second lower power line LPL2, and the third lower power line LPL3. The first insulating layer 102 may include an inorganic insulating material such as SiO₂, SiNₓ, silicon oxynitride (SiON), aluminum oxide (Al₂O₃), titanium oxide (TiO₂), tantalum oxide (Ta₂O₅), hafnium oxide (HfO₂), or zinc oxide (ZnO). The first insulating layer 102 may have a single-layer structure or a multi-layer structure. In an embodiment, the first insulating layer 102 may be a buffer layer.

The first thin-film transistor TFT1 may be disposed on the first insulating layer 102. The first thin-film transistor TFT1 may include a first semiconductor pattern ACT1, a first gate electrode GE1, a first source electrode SE1, and a first drain electrode DE1.

The second thin-film transistor TFT2 may be disposed on the first insulating layer 102. The second thin-film transistor TFT2 may include a second semiconductor pattern ACT2, a second gate electrode GE2, a second source electrode SE2, and a second drain electrode DE2.

The third thin-film transistor TFT3 may be disposed on the first insulating layer 102. The third thin-film transistor TFT3 may include a third semiconductor pattern ACT3, a third gate electrode GE3, a third source electrode SE3, and a third drain electrode DE3.

The first semiconductor layer 103 may be disposed on the first insulating layer 102. The first semiconductor layer 103 may include the first semiconductor pattern ACT1, the second semiconductor pattern ACT2, and the third semiconductor pattern ACT3. The first semiconductor pattern ACT1, the second semiconductor pattern ACT2, and the third semiconductor pattern ACT3 may be individually patterned.

The first semiconductor pattern ACT1 may include a source area overlapping the first source electrode SE1, a drain area overlapping the first drain electrode DE1, and a channel area between the source area and the drain area. The second semiconductor pattern ACT2 may include a source area overlapping the second source electrode SE2, a drain area overlapping the second drain electrode DE2, and a channel area between the source area and the drain area. The third semiconductor pattern ACT3 may include a source area overlapping the third source electrode SE3, a drain area overlapping the third drain electrode DE3, and a channel area between the source area and the drain area.

A second insulating layer 104 may be disposed on the first semiconductor layer 103. In an embodiment, the second insulating layer 104 may cover the entire first semiconductor layer 103. For example, the second insulating layer 104 may entirely cover the first semiconductor pattern ACT1, the second semiconductor pattern ACT2, and the third semiconductor pattern ACT3. In an embodiment, the second insulating layer 104 may be patterned to overlap the channel area of each of the first to third semiconductor patterns ACT1, ACT2, and ACT3. The second insulating layer 104 may include an inorganic insulating material such as SiO₂, SiNₓ, SiON, Al₂O₃, TiO₂, Ta₂O₅, HfO₂, or ZnO. The second insulating layer 104 may have a single-layer structure or a multi-layer structure. In an embodiment, the second insulating layer 104 may be a first gate insulating layer.

A second conductive layer 105 may be disposed on the second insulating layer 104. The second conductive layer 105 may include the first gate electrode GE1, the second gate electrode GE2, and the third gate electrode GE3. The first gate electrode GE1, the second gate electrode GE2, and the third gate electrode GE3 may be individually patterned. The first gate electrode GE1 may overlap the channel area of the first semiconductor pattern ACT1. The second gate electrode GE2 may overlap the channel area of the second semiconductor pattern ACT2. The third gate electrode GE3 may overlap the channel area of the third semiconductor pattern ACT3.

The second conductive layer 105 may include the first capacitor electrode CE1 of the storage capacitor Cst of each of the first to third subpixels SPX1, SPX2, and SPX3. In an embodiment, the first capacitor electrode CE1 of the first subpixel SPX1 may be formed integrally with the first gate electrode GE1, for example, as a single uninterrupted structure. In an embodiment, the first capacitor electrode CE1 of the second subpixel SPX2 may be formed integrally with the second gate electrode GE2, for example, as a single uninterrupted structure. In an embodiment, the first capacitor electrode CE1 of the third subpixel SPX3 may be formed integrally with the third gate electrode GE3, for example, as a single uninterrupted structure. The above embodiments are examples and, in embodiments, the gate electrodes and the first capacitor electrodes CE1 may be formed individually.

A third insulating layer 106 may be disposed on the second conductive layer 105. In an embodiment, the third insulating layer 106 may cover the entire second conductive layer 105. For example, the third insulating layer 106 may entirely cover the first gate electrode GE1, the second gate electrode GE2, and the third gate electrode GE3. The third insulating layer 106 may include an inorganic insulating material such as SiO₂, SiNₓ, SiON, Al₂O₃, TiO₂, Ta₂O₅, HfO₂, or ZnO. The third insulating layer 106 may have a single-layer structure or a multi-layer structure. In an embodiment, the third insulating layer 106 may be a second gate insulating layer.

A third conductive layer 107 may be disposed on the third insulating layer 106. The third conductive layer 107 may include the first power line PL1, the second power line PL2, and the third power line PL3. In an embodiment, the first power line PL1, the second power line PL2, and the third power line PL3 may be individually patterned. In an embodiment, the first power line PL1 and the second power line PL2 may be connected to each other. In an embodiment, the first power line PL1 and the third power line PL3 may be separated from each other. In an embodiment, the second power line PL2 and the third power line PL3 may be separated from each other.

The third conductive layer 107 may include the second capacitor electrode CE2 of the storage capacitor Cst of each of the first to third subpixels SPX1, SPX2, and SPX3. In an embodiment, the second capacitor electrode CE2 of the first subpixel SPX1 may be formed integrally with the first power line PL1, for example, as a single uninterrupted structure. In an embodiment, the second capacitor electrode CE2 of the second subpixel SPX2 may be formed integrally with the second power line PL2, for example, as a single uninterrupted structure. In an embodiment, the second capacitor electrode CE2 of the third subpixel SPX3 may be formed integrally with the third power line PL3, for example, as a single uninterrupted structure. The above embodiments are examples and, in embodiments, the power lines and the second capacitor electrodes CE2 may be formed individually.

In an embodiment, the first lower power line LPL1 may be connected (e.g., electrically) to the first power line PL1 through a contact hole defined in the first insulating layer 102, the second insulating layer 104, and the third insulating layer 106. In an embodiment, the first lower power line LPL1 may be in direct contact with the first power line PL1 through the contact hole defined in the first insulating layer 102, the second insulating layer 104, and the third insulating layer 106. In an embodiment, the first power voltage VDD1 (refer to FIG. 3A) may be applied to the first power line PL1. In an embodiment, the first power voltage VDD1 may also be applied to the first lower power line LPL1 through the first power line PL1.

In an embodiment, the second lower power line LPL2 may be connected (e.g., electrically) to the second power line PL2 through a contact hole defined in the first insulating layer 102, the second insulating layer 104, and the third insulating layer 106. In an embodiment, the second lower power line LPL2 may be in direct contact with the second power line PL2 through the contact hole defined in the first insulating layer 102, the second insulating layer 104, and the third insulating layer 106. In an embodiment, the second power voltage VDD2 (refer to FIG. 3B) may be applied to the second power line PL2. In an embodiment, the second power voltage VDD2 may also be applied to the second lower power line LPL2 through the second power line PL2.

In an embodiment, the third lower power line LPL3 may be connected (e.g., electrically) to the third power line PL3 through contact holes defined in the first insulating layer 102, the second insulating layer 104, and the third insulating layer 106. In an embodiment, the third lower power line LPL3 may be in direct contact with the third power line PL3 through contact holes defined in the first insulating layer 102, the second insulating layer 104, and the third insulating layer 106. In an embodiment, the third power voltage VDD3 (refer to FIG. 3C) may be applied to the third power line PL3. In an embodiment, the third power voltage VDD3 may also be applied to the third lower power line LPL3 through the third power line PL3.

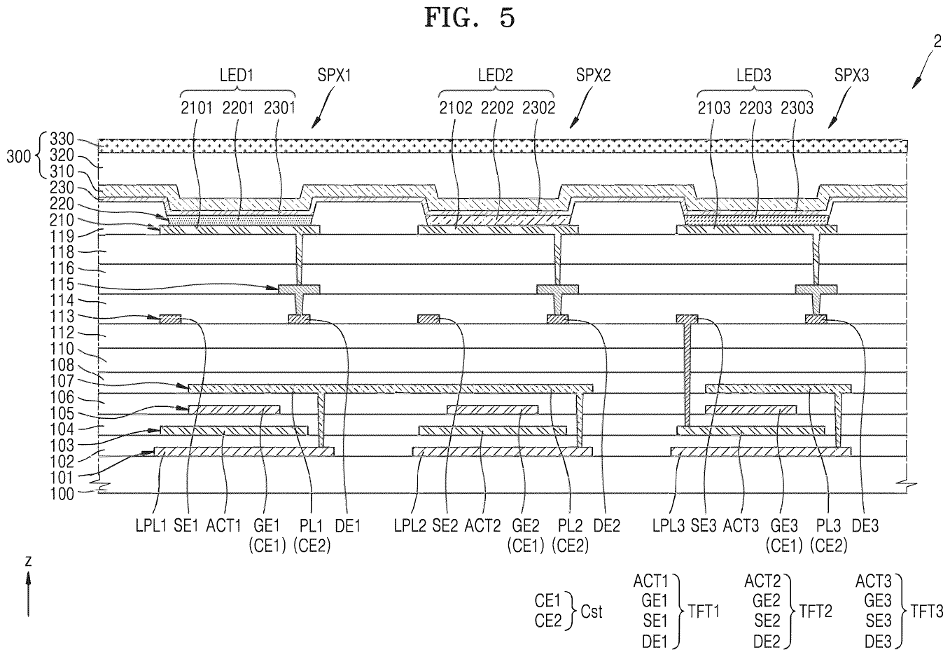

FIGS. 4A and 4B illustrate an embodiment in which the first power line PL1, the second power line PL2, and the third power line PL3 are respectively and individually connected to the first lower power line LPL1, the second lower power line LPL2, and the third lower power line LPL3, but the disclosure is not necessarily limited thereto. In an embodiment, the first power line PL1 and the second power line PL2 may be connected to each other, the first lower power line LPL1 may be connected to the first power line PL1, and the second lower power line LPL2 may be connected to the second power line PL2. In an embodiment, the first lower power line LPL1 and the second lower power line LPL2 may be connected to each other, the first power line PL1 may be connected to the first lower power line LPL1, and the second power line PL2 may be connected to the second lower power line LPL2. In embodiments, other various contact structures may be implemented. Embodiments showing various contact structures of the first power line PL1, the second power line PL2, the third power line PL3, the first lower power line LPL1, the second lower power line LPL2, and the third lower power line LPL3 are described below with reference to FIGS. 5 to 9.

A fourth insulating layer 108 may be disposed on the third conductive layer 107. In an embodiment, the fourth insulating layer 108 may cover the entire third conductive layer 107. For example, the fourth insulating layer 108 may entirely cover the first power line PL1, the second power line PL2, and the third power line PL3. The fourth insulating layer 108 may include an inorganic insulating material such as SiO₂, SiNₓ, SiON, Al₂O₃, TiO₂, Ta₂O₅, HfO₂, or ZnO. The fourth insulating layer 108 may have a single-layer structure or a multi-layer structure. In an embodiment, the fourth insulating layer 108 may be a first interlayer insulating layer.

A fifth insulating layer 110 may be disposed on the fourth insulating layer 108. In an embodiment, the fifth insulating layer 110 may cover the entire fourth insulating layer 108. The fifth insulating layer 110 may include an inorganic insulating material such as SiO₂, SiNₓ, SiON, Al₂O₃, TiO₂, Ta₂O₅, HfO₂, or ZnO. The fifth insulating layer 110 may have a single-layer structure or a multi-layer structure. In an embodiment, the fifth insulating layer 110 may be a third gate insulating layer. In an embodiment, a second semiconductor layer may be disposed between the fourth insulating layer 108 and the fifth insulating layer 110.

A sixth insulating layer 112 may be disposed on the fifth insulating layer 110. In an embodiment, the sixth insulating layer 112 may entirely cover the fifth insulating layer 110. The sixth insulating layer 112 may include an inorganic insulating material such as SiO₂, SiNₓ, SiON, Al₂O₃, TiO₂, Ta₂O₅, HfO₂, or ZnO. The sixth insulating layer 112 may have a single-layer structure or a multi-layer structure. In an embodiment, the sixth insulating layer 112 may be a second interlayer insulating layer. In an embodiment, an additional conductive layer may be disposed between the fifth insulating layer 110 and the sixth insulating layer 112.

A fourth conductive layer 113 may be disposed on the sixth insulating layer 112. The fourth conductive layer 113 may include the first source electrode SE1, the first drain electrode DE1, the second source electrode SE2, the second drain electrode DE2, the third source electrode SE3, and the third drain electrode DE3. In an embodiment, the first source electrode SE1, the first drain electrode DE1, the second source electrode SE2, the second drain electrode DE2, the third source electrode SE3, and the third drain electrode DE3 may be individually patterned.

The first source electrode SE1 may be connected to the source area of the first semiconductor pattern ACT1 through a contact hole defined in the second to sixth insulating layers 104, 106, 108, 110, and 112. The second source electrode SE2 may be connected to the source area of the second semiconductor pattern ACT2 through a contact hole defined in the second to sixth insulating layers 104, 106, 108, 110, and 112. The third source electrode SE3 may be connected to the source area of the third semiconductor pattern ACT3 through a contact hole defined in the second to sixth insulating layers 104, 106, 108, 110, and 112.

Referring to FIG. 4B, the first drain electrode DE1 may be connected to the drain area of the first semiconductor pattern ACT1 through a contact hole defined in the second to sixth insulating layers 104, 106, 108, 110, and 112. The first power line PL1 may be partially open to allow the first drain electrode DE1 to pass through. The second drain electrode DE2 may be connected to the drain area of the second semiconductor pattern ACT2 through a contact hole defined in the second to sixth insulating layers 104, 106, 108, 110, and 112. The second power line PL2 may be partially opened to allow the second drain electrode DE2 to pass through. The third drain electrode DE3 may be connected to the drain area of the third semiconductor pattern ACT3 through a contact hole defined in the second to sixth insulating layers 104, 106, 108, 110, and 112. The third power line PL3 may be partially open to allow the third drain electrode DE3 to pass through.

A seventh insulating layer 114 may be disposed on the fourth conductive layer 113. In an embodiment, the seventh insulating layer 114 may cover the entire fourth conductive layer 113. In an embodiment, the seventh insulating layer 114 may generally cover the first source electrode SE1, the first drain electrode DE1, the second source electrode SE2, the second drain electrode DE2, the third source electrode SE3, and the third drain electrode DE3. The seventh insulating layer 114 may include an organic insulating material, such as polyimide (PI), acryl, benzocyclobutene (BCB), hexamethyldisiloxane (HMDSO), or the like. In an embodiment, the seventh insulating layer 114 may be a first via layer.

The fifth conductive layer 115 may be disposed on the seventh insulating layer 114. The fifth conductive layer 115 may include contact metals respectively overlapping the first drain electrode DE1, the second drain electrode DE2, and the third drain electrode DE3. The contact metals of the fifth conductive layer 115 may be respectively connected to the first drain electrode DE1, the second drain electrode DE2, and the third drain electrode DE3 through corresponding contact holes defined in the seventh insulating layer 114.

An eighth insulating layer 116 may be disposed on the fifth conductive layer 115. In an embodiment, the eighth insulating layer 116 may cover the entire fifth conductive layer 115. In an embodiment, the eighth insulating layer 116 may cover the entire contact metals of the fifth conductive layer 115. The eighth insulating layer 116 may include an organic insulating material, such as PI, acryl, BCB, HMDSO, or the like. In an embodiment, the eighth insulating layer 116 may be a second via layer.

A ninth insulating layer 118 may be disposed on the eighth insulating layer 116. In an embodiment, the ninth insulating layer 118 may cover the entire eighth insulating layer 116. The ninth insulating layer 118 may include an organic insulating material, such as PI, acryl, BCB, HMDSO, or the like. In an embodiment, the ninth insulating layer 118 may be a third via layer. In an embodiment, an additional conductive layer may be disposed between the eighth insulating layer 116 and the ninth insulating layer 118.

The first light-emitting diode LED1, the second light-emitting diode LED2, and the third light-emitting diode LED3 may be disposed on the ninth insulating layer 118. The first light-emitting diode LED1 may include the first subpixel electrode 2101, a first intermediate layer 2201, and the first counter electrode 2301. The second light-emitting diode LED2 may include the second subpixel electrode 2102, a second intermediate layer 2202, and the second counter electrode 2302. The third light-emitting diode LED3 may include the third subpixel electrode 2103, a third intermediate layer 2203, and the third counter electrode 2303.

A subpixel electrode 210 may be disposed on the ninth insulating layer 118. The subpixel electrode 210 may include the first subpixel electrode 2101, the second subpixel electrode 2102, and the third subpixel electrode 2103. The first subpixel electrode 2101, the second subpixel electrode 2102, and the third subpixel electrode 2103 may be individually patterned and may be spaced apart from each other.

The first subpixel electrode 2101 may be connected to the first semiconductor pattern ACT1 through the contact metal of the fifth conductive layer 115 and the first drain electrode DE1. In an embodiment, an additional contact metal disposed between the eighth insulating layer 116 and the ninth insulating layer 118 may be provided between the first subpixel electrode 2101 and the contact metal of the fifth conductive layer 115.

The second subpixel electrode 2102 may be connected to the second semiconductor pattern ACT2 through the contact metal of the fifth conductive layer 115 and the second drain electrode DE2. In an embodiment, an additional contact metal disposed between the eighth insulating layer 116 and the ninth insulating layer 118 may be provided between the second subpixel electrode 2102 and the contact metal of the fifth conductive layer 115.

The third subpixel electrode 2103 may be connected to the third semiconductor pattern ACT3 through the contact metal of the fifth conductive layer 115 and the third drain electrode DE3. In an embodiment, an additional contact metal disposed between the eighth insulating layer 116 and the ninth insulating layer 118 may be provided between the third subpixel electrode 2103 and the contact metal of the fifth conductive layer 115.

The subpixel electrode 210 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). The subpixel electrode 210 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. The structure and materials of the subpixel electrode 210 are not necessarily limited thereto, and various modifications may be possible.

A pixel defining layer 119 may be disposed on the subpixel electrode 210. An opening overlapping each subpixel electrode 210 may be defined in the pixel defining layer 119. For example, an opening overlapping the first subpixel electrode 2101, an opening overlapping the second subpixel electrode 2102, and an opening overlapping the third subpixel electrode 2103 may be defined in the pixel defining layer 119. Each opening of the pixel defining layer 119 may define an emission area of a corresponding light-emitting diode. For example, an opening in the pixel defining layer 119 overlapping the first subpixel electrode 2101 may define an emission area of a first light-emitting diode LED1. Similarly, the opening of the pixel defining layer 119 overlapping the second subpixel electrode 2102 may define an emission area of the second light-emitting diode LED2. Similarly, the opening of the pixel defining layer 119 overlapping the third subpixel electrode 2103 may define an emission area of the third light-emitting diode LED3.

An intermediate layer 220 may be disposed on the subpixel electrode 210. The intermediate layer 220 may include the first intermediate layer 2201, the second intermediate layer 2202, and the third intermediate layer 2203. The first intermediate layer 2201 may be disposed on the first subpixel electrode 2101. The second intermediate layer 2202 may be disposed on the second subpixel electrode 2102. The third intermediate layer 2203 may be disposed on the third subpixel electrode 2103.

The intermediate layer 220 may include an emission layer and a functional layer. The emission layer may include a small molecule or large molecule material that emits light when a certain voltage is applied. The functional layer may include at least one of an electron transport layer (ETL), an electron injection layer (EIL), a hole transport layer (HTL), and a hole injection layer (HIL). In an embodiment, the intermediate layer 220 may include the first intermediate layer 2201, the second intermediate layer 2202, and the third intermediate layer 2203 which may be apart from each other and individually patterned. In an embodiment, a portion of the intermediate layer 220 may be integrally disposed, for example, as a single uninterrupted structure, across the first light-emitting diode LED1, the second light-emitting diode LED2, and the third light-emitting diode LED3. For example, at least a portion of the functional layer of the intermediate layer 220 may be integrally disposed, as a single uninterrupted structure, across the first light-emitting diode LED1, the second light-emitting diode LED2, and the third light-emitting diode LED3. In an embodiment, the intermediate layer 220 may be integrally disposed, for example, as a single uninterrupted structure, across the first light-emitting diode LED1, the second light-emitting diode LED2, and the third light-emitting diode LED3. In an embodiment, portions of the intermediate layer 220 that overlap the first to third subpixel electrodes 2101, 2102, and 2103 may be the first to third intermediate layers 2201, 2202, and 2203. The intermediate layer 220 may have any structure including an emission layer that emits light. In an embodiment, the intermediate layer 220 may include a tandem structure.

A counter electrode 230 may be disposed on the intermediate layer 220. The counter electrode 230 may be integrally disposed, for example, as a single uninterrupted structure, across the first light-emitting diode LED1, the second light-emitting diode LED2, and the third light-emitting diode LED3. A portion of the counter electrode 230 overlapping the first subpixel electrode 2101 may be the first counter electrode 2301, a portion of the counter electrode 230 overlapping the second subpixel electrode 2102 may be the second counter electrode 2302, and a portion of the counter electrode 230 overlapping the third subpixel electrode 2103 may be the third counter electrode 2303.

The counter electrode 230 may include a conductive material having a low work function. For example, the counter electrode 230 may include a transparent (or transflective) layer including Ag, Mg, Al, Pt, Pd, Au, Ni, Nd, Ir, Cr, Li, Ca, or an alloy thereof. In embodiments, the counter electrode 230 may further include a layer including a material such as ITO, IZO, ZnO, or In₂O₃ on a transparent layer (or transflective layer) including the aforementioned materials.

An encapsulation layer 300 may be disposed on the counter electrode 230. The encapsulation layer 300 may include at least one inorganic encapsulation layer and at least one organic encapsulation layer. In an embodiment, the encapsulation layer 300 may include a first inorganic encapsulation layer 310, a second inorganic encapsulation layer 330, and an organic encapsulation layer 320 between the first inorganic encapsulation layer 310 and the second inorganic encapsulation layer 330.

The first inorganic encapsulation layer 310 and the second inorganic encapsulation layer 330 may include at least one of SiO₂, SiNₓ, SiON, Al₂O₃, TiO₂, Ta₂O₅, HfO₂, ZnO, or the like. The organic encapsulation layer 320 may include a polymer-based material. The polymer-based material may include silicon-based resins, acryl-based resins, epoxy-based resins, polyimide, polyethylene, etc.

FIG. 5 is a cross-sectional view of the display device 2 according to an embodiment.

Referring to FIG. 5, the first power line PL1 may be connected to the second power line PL2. For example, the first power line PL1 and the second power line PL2 may be formed integrally, as a single uninterrupted structure. The first power line PL1 and the second power line PL2, which are connected to each other, may be separated from the third power line PL3.

At least one of the first lower power line LPL1 and the second lower power line LPL2 may be connected to the first power line PL1 and the second power line PL2 through a contact hole. In an embodiment, the first lower power line LPL1 may be connected to the first power line PL1 through a contact hole, and may further be connected to the second power line PL2. In an embodiment, the second lower power line LPL2 may be connected to the second power line PL2 through a contact hole, and may further be connected to the first power line PL1. In an embodiment, as illustrated in FIG. 5, the first lower power line LPL1 may be connected to the first power line PL1 through a contact hole, the second lower power line LPL2 may be connected to the second power line PL2 through a contact hole, and the first power line PL1 and the second power line PL2 may be formed integrally, for example, as a single uninterrupted structure, and may be connected to each other.

In an embodiment, since the first power line PL1 and the second power line PL2 may be connected to each other, the same voltage may be applied to the first power line PL1 and the second power line PL2. For example, the first power voltage VDD1 (refer to FIG. 3A) may be equal to the second power voltage VDD2 (refer to FIG. 3B). Accordingly, the same voltage (e.g., the first power voltage VDD1 or the second power voltage VDD2) may be applied to the first lower power line LPL1 and the second lower power line LPL2.

The third lower power line LPL3 may be connected to the third power line PL3 through a contact hole. The third power voltage VDD3 (refer to FIG. 3C) may be applied to the third power line PL3. Accordingly, the third power voltage VDD3 may also be applied to the third lower power line LPL3.

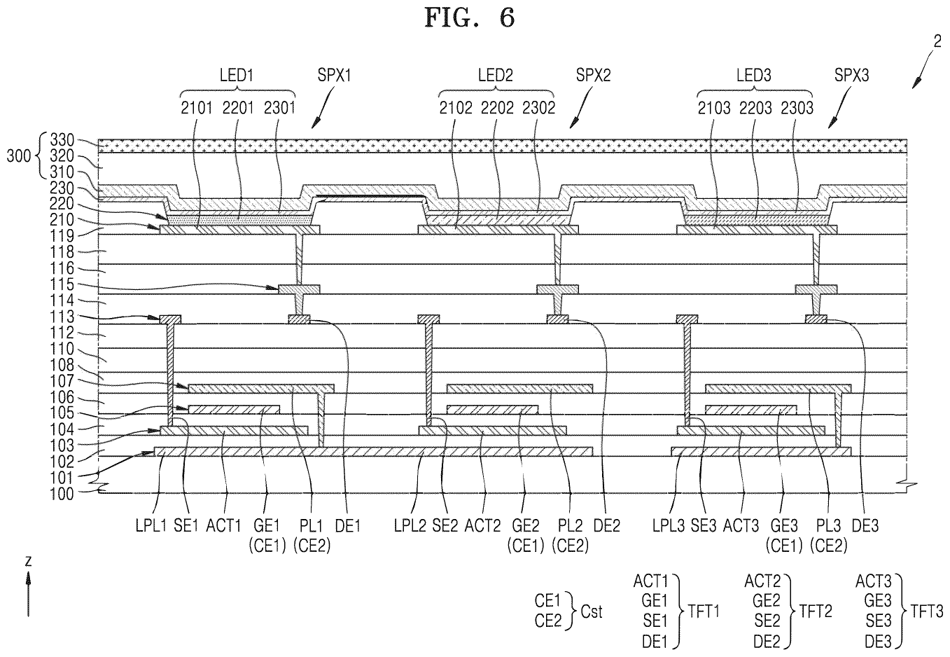

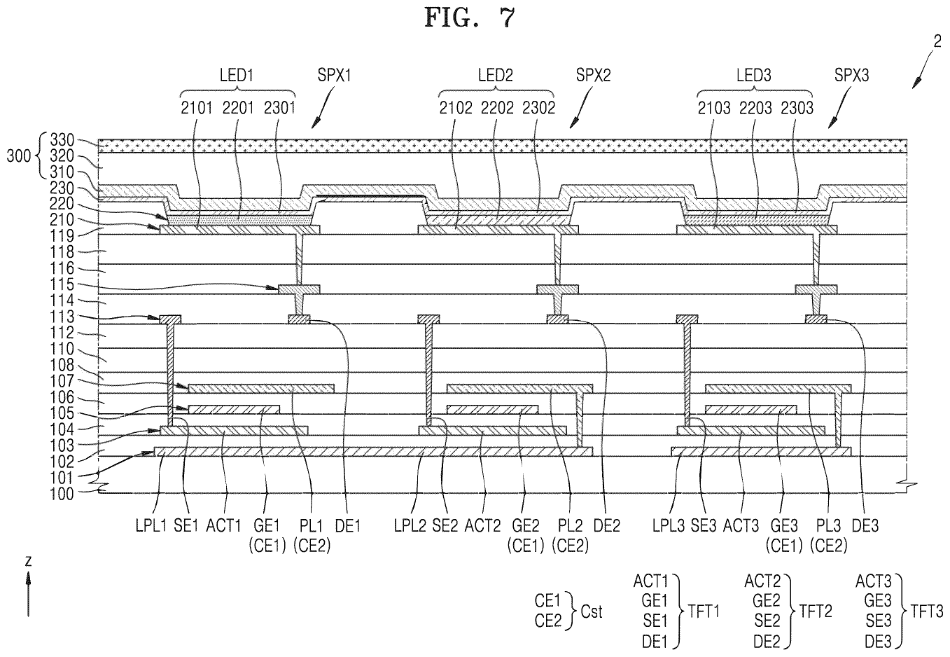

FIG. 6 is a cross-sectional view of the display device 2 according to an embodiment. FIG. 7 is a cross-sectional view of the display device 2 according to an embodiment.

Referring to FIGS. 6 and 7, the first lower power line LPL1 may be connected to the second lower power line LPL2. For example, the first lower power line LPL1 and the second lower power line LPL2 may be formed integrally, as a single uninterrupted structure. The first lower power line LPL1 and the second lower power line LPL2, which are connected to each other, may be separated from the third lower power line LPL3. The first lower power line LPL1 and the second lower power line LPL2, which are connected to each other, may be connected to at least one of the first power line PL1 and the second power line PL2.

Referring to FIG. 6, the first power line PL1 may be connected to the first lower power line LPL1 via a contact hole. Accordingly, the first power line PL1 may be connected to the second lower power line LPL2 via the first lower power line LPL1. In an embodiment, the second power line PL2 and the second lower power line LPL2 may be separated from each other. In an embodiment, the first power voltage VDD1 (refer to FIG. 3A) may be applied to the first power line PL1. Accordingly, the first power voltage VDD1 may also be applied to the first lower power line LPL1 and the second lower power line LPL2.

Referring to FIG. 7, the second power line PL2 may be connected to the second lower power line LPL2 via a contact hole. Accordingly, the second power line PL2 may be connected to the first lower power line LPL1 via the second lower power line LPL2. In an embodiment, the first power line PL1 may be separated from the first lower power line LPL1. In an embodiment, the second power voltage VDD2 (refer to FIG. 3B) may be applied to the second power line PL2. Accordingly, the second power voltage VDD2 may also be applied to the first lower power line LPL1 and the second lower power line LPL2.

In an embodiment, the first lower power line LPL1 and the second lower power line LPL2 may be formed integrally, for example, as a single uninterrupted structure, the first power line PL1 may be connected to the first lower power line LPL1 through a contact hole, and the second power line PL2 may be connected to the second lower power line LPL2 through a contact hole.

In an embodiment, the first power voltage VDD1 may be the same as the second power voltage VDD2. Accordingly, in embodiments illustrated in FIGS. 6 and 7, the same voltage (e.g., the first power voltage VDD1 or the second power voltage VDD2) may be applied to the first power line PL1, the second power line PL2, the first lower power line LPL1, and the second lower power line LPL2.

The third lower power line LPL3 may be connected to the third power line PL3 through a contact hole. The third power voltage VDD3 (refer to FIG. 3C) may be applied to the third power line PL3. Accordingly, the third power voltage VDD3 may also be applied to the third lower power line LPL3.

Combinations of the embodiments illustrated in FIGS. 5, 6, and 7 may also be within the scope of the disclosure. For example, in an embodiment, the first power line PL1 and the second power line PL2 may be formed integrally, as a single uninterrupted structure. The first lower power line LPL1 and the second lower power line LPL2 may be formed integrally, for example, as a single uninterrupted structure, and the first power line PL1 may be connected to the first lower power line LPL1 through a contact hole. In an embodiment, the first power line PL1 and the second power line PL2 may be formed integrally, for example, as a single uninterrupted structure. The first lower power line LPL1 and the second lower power line LPL2 may be formed integrally, for example, as a single uninterrupted structure, and the second power line PL2 may be connected to the second lower power line LPL2 through a contact hole. In an embodiment, the first power line PL1 and the second power line PL2 may be formed integrally, for example, as a single uninterrupted structure. The first lower power line LPL1 and the second lower power line LPL2 may be formed integrally, for example, as a single uninterrupted structure, and the first power line PL1 may be connected to the first lower power line LPL1 through a contact hole. In embodiments, the second power line PL2 may be connected to the second lower power line LPL2 through a contact hole.

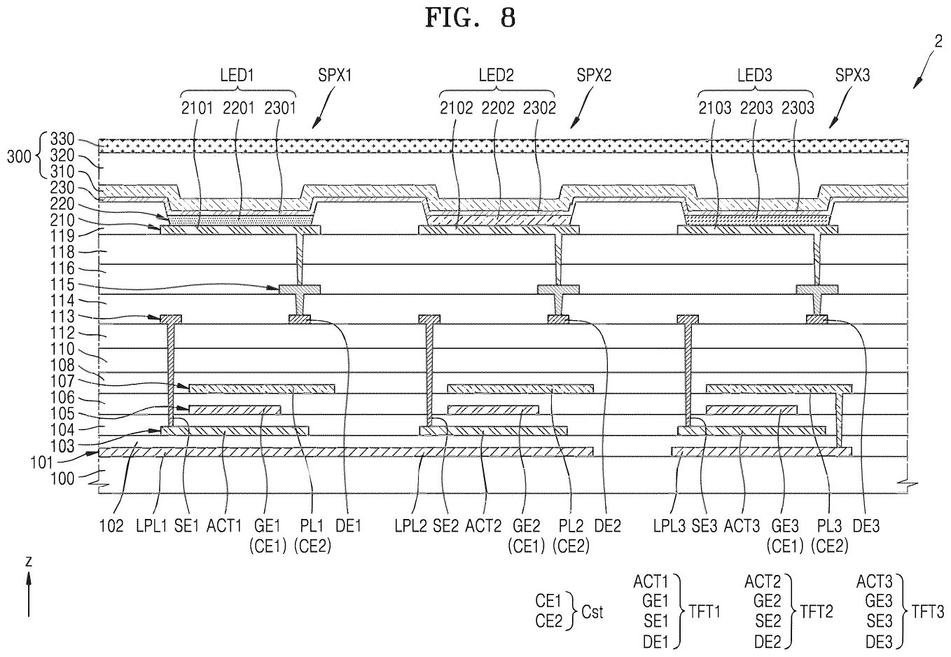

FIG. 8 is a cross-sectional view of the display device 2 according to an embodiment.

Referring to FIGS. 1 and 8, the first lower power line LPL1 and the second lower power line LPL2 may be connected to each other. For example, the first lower power line LPL1 and the second lower power line LPL2 may be formed integrally, as a single uninterrupted structure. The first lower power line LPL1 and the second lower power line LPL2 may be separated from the third lower power line LPL3.

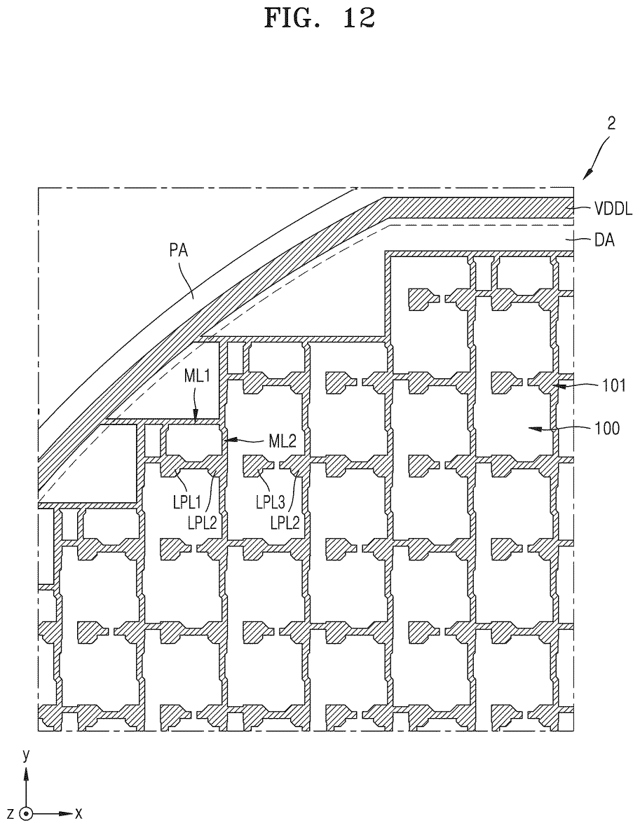

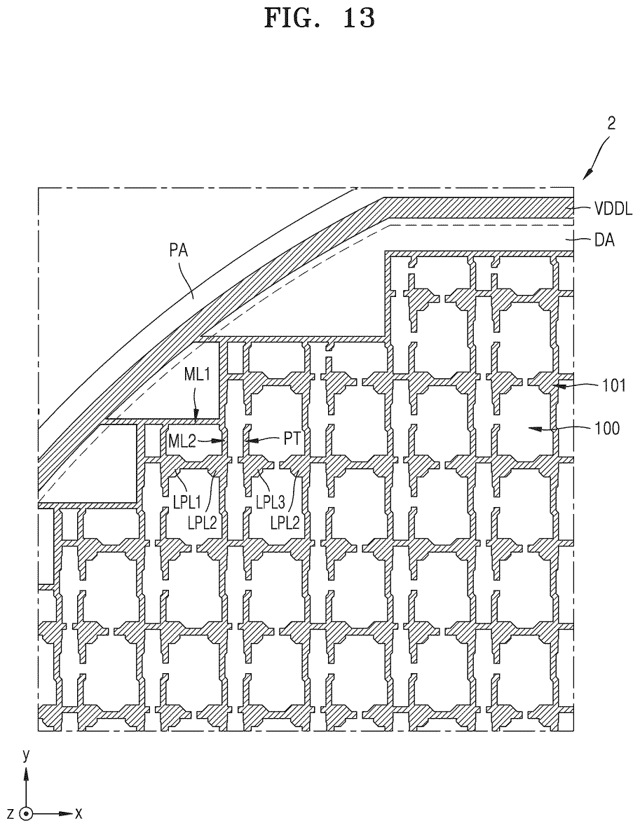

The display device 2 may include the display area DA and the peripheral area PA. The first to third subpixels SPX1, SPX2, and SPX3 may be arranged in the display area DA. The first lower power line LPL1 and the second lower power line LPL2 may be formed integrally, for example, as a single uninterrupted structure, and may extend from the display area DA to the peripheral area PA. In the peripheral area PA, the first lower power line LPL1 and the second lower power line LPL2 may receive a power voltage (e.g., the first power voltage VDD1 (refer to FIG. 3A) or the second power voltage VDD2 (refer to FIG. 3B)) through a separate power line. The connection structure of the first lower power line LPL1, the second lower power line LPL2, and the power line in the peripheral area PA is described herein with reference to FIGS. 12 and 13. In an embodiment, the first power line PL1 may be separated from the first lower power line LPL1. In an embodiment, the second power line PL2 may be separated from the second lower power line LPL2. In an embodiment, the first power voltage VDD1 may be the same as the second power voltage VDD2.

The third lower power line LPL3 may be connected to the third power line PL3 through a contact hole. The third power voltage VDD3 (refer to FIG. 3C) may be applied to the third power line PL3. Accordingly, the third power voltage VDD3 may also be applied to the third lower power line LPL3.

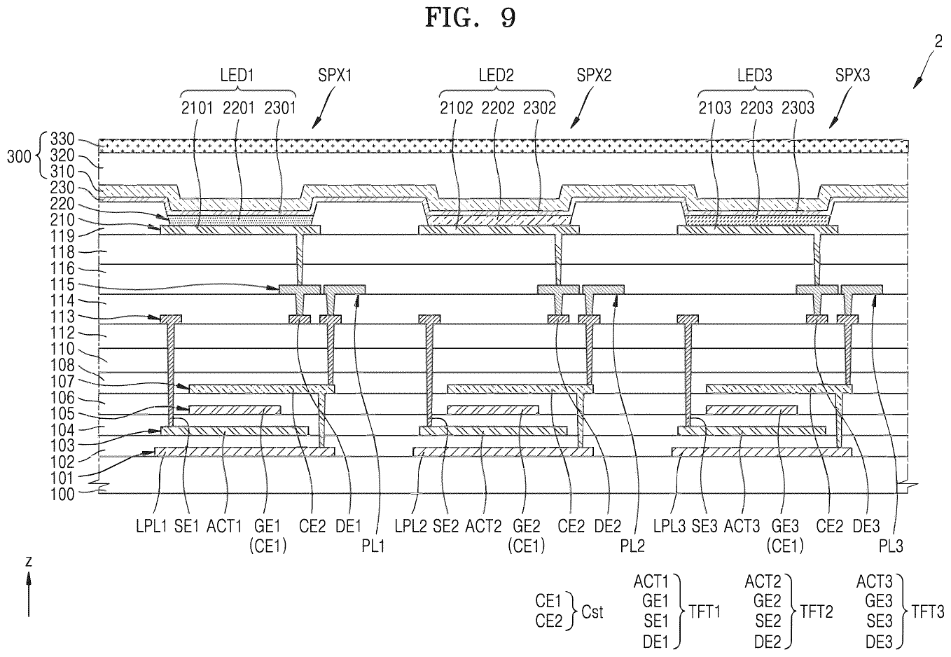

FIG. 9 is a cross-sectional view of the display device 2 according to an embodiment.

Referring to FIG. 9, the first power line PL1, the second power line PL2, and the third power line PL3 may be disposed in the fifth conductive layer 115.

In an embodiment, the first power line PL1 may be connected to a contact metal disposed in the fourth conductive layer 113 through a contact hole defined in the seventh insulating layer 114. The contact metal disposed in the fourth conductive layer 113 may be connected to the second capacitor electrode CE2 of the first subpixel SPX1 through a contact hole defined in the fourth to sixth insulating layers 108, 110, and 112. The first lower power line LPL1 may be connected to the second capacitor electrode CE2 of the first subpixel SPX1 through a contact hole defined in the first to third insulating layers 102, 104, and 106. Accordingly, the first lower power line LPL1 may be connected to the first power line PL1.

In some embodiments, the first power line PL1 may include a portion disposed in the fifth conductive layer 115, a portion disposed in the fourth conductive layer 113, and a portion disposed in the third conductive layer 107. In embodiments, a portion of the first power line PL1 disposed in the third conductive layer 107 may be formed integrally, for example, as a single uninterrupted structure, with the second capacitor electrode CE2 of the first subpixel SPX1. In embodiments, the first lower power line LPL1 may be connected to a portion of the first power line PL1 disposed in the third conductive layer 107 through a contact hole defined in the first to third insulating layers 102, 104, and 106.

In an embodiment, the second power line PL2 may be connected to a contact metal disposed in the fourth conductive layer 113 through a contact hole defined in the seventh insulating layer 114. The contact metal disposed in the fourth conductive layer 113 may be connected to the second capacitor electrode CE2 of the second subpixel SPX2 through a contact hole defined in the fourth to sixth insulating layers 108, 110, and 112. The second lower power line LPL2 may be connected to the second capacitor electrode CE2 of the second subpixel SPX2 through a contact hole defined in the first to third insulating layers 102, 104, and 106. Accordingly, the second lower power line LPL2 may be connected to the second power line PL2.

In some embodiments, the second power line PL2 may include a portion disposed in the fifth conductive layer 115, a portion disposed in the fourth conductive layer 113, and a portion disposed in the third conductive layer 107. In embodiments, a portion of the second power line PL2 disposed in the third conductive layer 107 may be formed integrally, for example, as a single uninterrupted structure, with the second capacitor electrode CE2 of the second subpixel SPX2. In embodiments, the second lower power line LPL2 may be connected to a portion of the second power line PL2 disposed in the third conductive layer 107 through a contact hole defined in the first to third insulating layers 102, 104, and 106.

In an embodiment, the third power line PL3 may be connected to a contact metal disposed in the fourth conductive layer 113 through a contact hole defined in the seventh insulating layer 114. The contact metal disposed in the fourth conductive layer 113 may be connected to the second capacitor electrode CE2 of the third subpixel SPX3 through a contact hole defined in the fourth to sixth insulating layers 108, 110, and 112. The third lower power line LPL3 may be connected to the second capacitor electrode CE2 of the third subpixel SPX3 through a contact hole defined in the first to third insulating layers 102, 104, and 106. Accordingly, the third lower power line LPL3 may be connected to the third power line PL3.

In some embodiments, the third power line PL3 may include a portion disposed in the fifth conductive layer 115, a portion disposed in the fourth conductive layer 113, and a portion disposed in the third conductive layer 107. In an embodiment, a portion of the third power line PL3 disposed in the third conductive layer 107 may be formed integrally, for example, as a single uninterrupted structure, with the second capacitor electrode CE2 of the third subpixel SPX3. In embodiments, the third lower power line LPL3 may be connected to a portion of the third power line PL3 disposed in the third conductive layer 107 through a contact hole defined in the first to third insulating layers 102, 104, and 106.

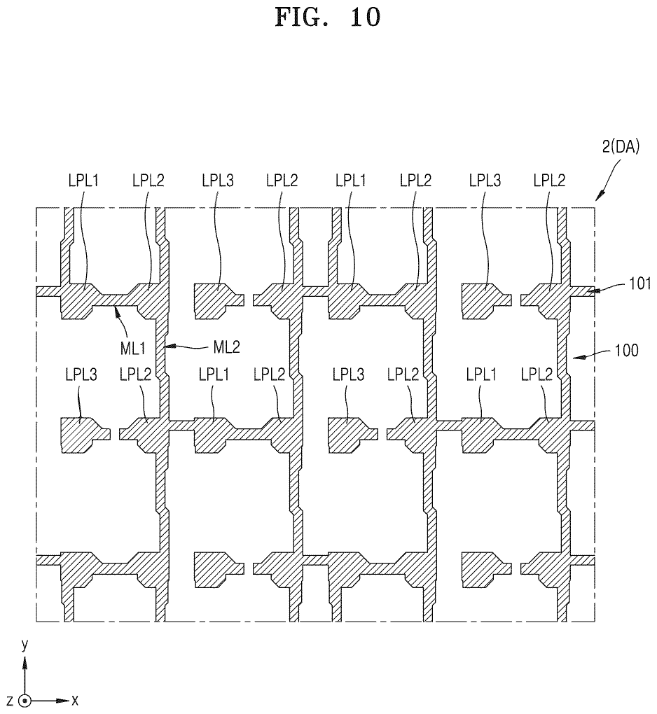

FIG. 10 is a plan view of a portion of the display device 2 according to an embodiment.

Referring to FIG. 10, the first lower power line LPL1 and the second lower power line LPL2 may be formed integrally, for example, as a single uninterrupted structure, and may have an overall mesh structure. For example, the first lower power line LPL1 may be connected to the second lower power line LPL2 through a first mesh line ML1 extending in a first direction (e.g., the x direction) and a second mesh line ML2 extending in a second direction (e.g., the y direction). The plurality of first lower power lines LPL1, the plurality of second lower power lines LPL2, the plurality of first mesh lines ML1, and the plurality of second mesh lines ML2 may be disposed in the display area DA. The plurality of first lower power lines LPL1, the plurality of second lower power lines LPL2, the plurality of first mesh lines ML1, and the plurality of second mesh lines ML2 may be connected to each other and form an overall mesh structure. For example, the first lower power line LPL1 and the second lower power line LPL2 may together have a mesh structure.

The third lower power lines LPL3 may be respectively disposed in the openings of the mesh structure. The third lower power line LPL3 may have an island shape. For example, the third lower power line LPL3 might not be connected to the first mesh line ML1 or the second mesh line ML2 and may be spaced apart from the first lower power line LPL1 and the second lower power line LPL2.

The arrangement of the first lower power line LPL1, the second lower power line LPL2, and the third lower power line LPL3 illustrated in FIG. 10 may correspond to the arrangement of the subpixels SPX1, SPX2, and SPX3 described with reference to FIG. 2A.

The first lower power line LPL1, the second lower power line LPL2, the third lower power line LPL3, and the second lower power line LPL2 may be sequentially disposed in the first direction (e.g., the x direction). The first mesh line ML1 may be disposed between the first lower power line LPL1 and the second lower power line LPL2. The first mesh line ML1 might not be disposed between the first lower power line LPL1 and the third lower power line LPL3. The first mesh line ML1 might not be disposed between the second lower power line LPL2 and the third lower power line LPL3.

The first lower power line LPL1 and the third lower power line LPL3 may be arranged alternately in the second direction (e.g., the y direction). A second mesh line ML2 might not be disposed between the first lower power line LPL1 and the third lower power line LPL3. The second lower power lines LPL2 may be disposed in the second direction (e.g., y direction). The second mesh line ML2 may be disposed between the second lower power lines LPL2.

However, the disclosure is not necessarily limited to the above arrangements. The first lower power line LPL1, the second lower power line LPL2, and the third lower power line LPL3 may have the aforementioned mesh and island structures and may be arranged correspondingly to FIGS. 2B, 2C, or may have other arrangements of the subpixels SPX1, SPX2, and SPX3.

The structure of the first to third lower power lines LPL1, LPL2, and LPL3 according to an embodiment may be implemented by individually patterning the mesh structure of the first lower power line LPL1 and the second lower power line LPL2, and the island structure of the third lower power line LPL3.

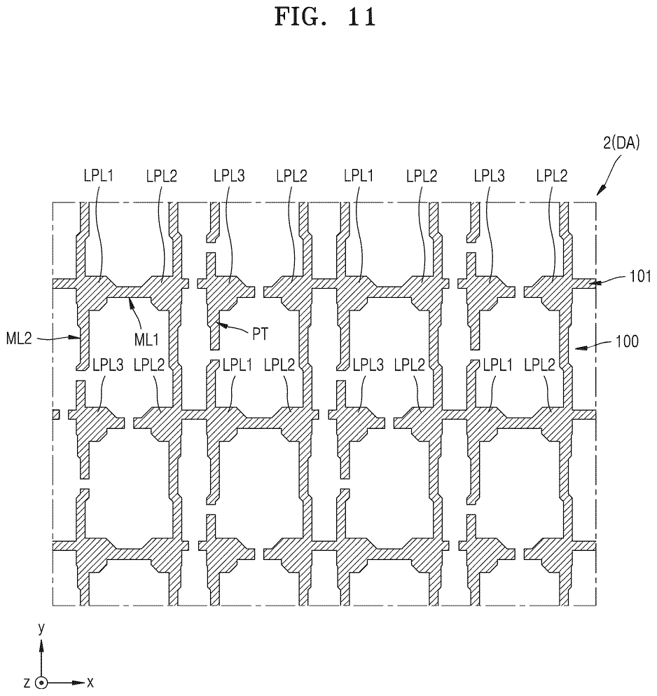

FIG. 11 is a plan view of a portion of the display device 2 according to an embodiment. Descriptions of features of the embodiment illustrated in FIG. 11 that overlap those of the embodiment illustrated in FIG. 10 are omitted. To the extent that an element is not described in detail with respect to a figure, it may be understood that the element is at least similar to a corresponding element that has been described elsewhere within the present disclosure.

Referring to FIG. 11, portions of the first and second mesh lines ML1 and ML2 may remain between the first lower power line LPL1 and the third lower power line LPL3, and between the second lower power line LPL2 and the third lower power line LPL3. For example, a portion of a disconnected second mesh line ML2 may be disposed between the first lower power line LPL1 and the third lower power line LPL3. Similarly, a portion of a disconnected first mesh line ML1 may be disposed between the second lower power line LPL2 and the third lower power line LPL3.

In some embodiments, the island structure of the third lower power line LPL3 may include protrusions PT pointing toward the first lower power line LPL1 or the second lower power line LPL2. For example, a portion of the third lower power line LPL3 may extend (or protrude) in the second direction (e.g., the y direction) toward the first lower power line LPL1 adjacent to the third lower power line LPL3. In embodiments, a portion of the first lower power line LPL1 may extend (or protrude) in the second direction (e.g., the y direction) toward the third lower power line LPL3 adjacent to the first lower power line LPL1. Similarly, a portion of the third lower power line LPL3 may extend (or protrude) in the first direction (e.g., the x direction) toward the second lower power line LPL2 adjacent to the third lower power line LPL3. In embodiments, a portion of the second lower power line LPL2 may extend (or protrude) in the first direction (e.g., the x direction) toward the third lower power line LPL3 adjacent to the second lower power line LPL2.

After including the above protrusion structures, in embodiments, the first lower power line LPL1 and the second lower power line LPL2 may be separated from the third lower power line LPL3.

The structure of the first to third lower power lines LPL1, LPL2, and LPL3, according to embodiments may be implemented by cutting the first and second mesh lines ML1 and ML2 connected to the third lower power line LPL3 in the structure in which the first to third lower power lines LPL1, LPL2, and LPL3 are connected through the first and second mesh lines ML1 and ML2.

FIG. 12 is a plan view of a portion of the display device 2 according to an embodiment. FIG. 13 is a plan view of a portion of the display device 2 according to an embodiment.

The embodiment illustrated in FIG. 12 may correspond to the embodiment illustrated in FIG. 10, and the embodiment illustrated in FIG. 13 may correspond to the embodiment illustrated in FIG. 11. In embodiments, FIGS. 12 and 13 may correspond to the embodiment described above with reference to FIG. 8.

Referring to FIGS. 12 and 13, the first lower power line LPL1 and the second lower power line LPL2 may be formed integrally, for example, as a single uninterrupted structure. The first lower power line LPL1 and the second lower power line LPL2 may extend beyond the display area DA, for example, to the peripheral area PA. For example, a portion of the mesh structure of the first lower power line LPL1 and the second lower power line LPL2 (e.g., the first mesh line ML1) may extend to the peripheral area PA.

The first lower power line LPL1 and the second lower power line LPL2 may be connected to a power voltage line VDDL disposed in the peripheral area PA. For example, a portion of the mesh structure of the first lower power line LPL1 and the second lower power line LPL2 (e.g., the first mesh line ML1) may be connected to the power voltage line VDDL in the peripheral area PA. The first lower power line LPL1 and the second lower power line LPL2 may receive a power voltage (e.g., the first power voltage VDD1 (refer to FIG. 3A) or the second power voltage VDD2 (refer to FIG. 3B)) through the power voltage line VDDL. In an embodiment, the first power voltage VDD1 may be the same as the second power voltage VDD2.

As described above with reference to FIG. 8, the third lower power line LPL3 may be connected to the third power line PL3 (refer to FIG. 8) and may receive the third power voltage VDD3 (refer to FIG. 3C).

According to embodiments, a display device, in which a voltage may be individually applied to a lower power line, and an electronic device including the display device, are provided. In embodiments, a power voltage corresponding to each semiconductor pattern of each subpixel may be applied to the lower power line.

In embodiments, a reverse bias formed in a semiconductor pattern of each subpixel may be eliminated or at least reduced compared to when the same power voltage is applied to the lower power lines of all subpixels. For example, a body effect occurring in the semiconductor pattern of each subpixel may be eliminated or at least reduced.

In embodiments, a threshold voltage of the semiconductor pattern of each subpixel may be reduced or at least prevented from increasing.

In embodiments, power consumption required to drive the display device may be reduced. For example, a display device including low-power operation may be provided.

Those skilled in the art will recognize that the present disclosure can be practiced in other specific ways without departing from its technical spirit or essential characteristics. The described embodiments should be regarded as illustrative rather than being restrictive in all aspects. Although embodiments of the present disclosure have been described with reference to the accompanying drawings, the disclosure is not necessarily limited to these embodiments and may be implemented in various forms.

What is claimed is:

1. A display device, comprising:
a first subpixel circuit comprising a first thin-film transistor, the first thin-film transistor comprising a first semiconductor pattern;
a second subpixel circuit comprising a second thin-film transistor, the second thin-film transistor comprising a second semiconductor pattern;
a third subpixel circuit comprising a third thin-film transistor, the third thin-film transistor comprising a third semiconductor pattern;
a first power line disposed on the first semiconductor pattern, the first power line configured to apply a first power voltage to the first subpixel circuit;
a second power line disposed on the second semiconductor pattern, the second power line configured to apply a second power voltage to the second subpixel circuit;
a third power line disposed on the third semiconductor pattern, the third power line configured to apply a third power voltage to the third subpixel circuit;
a first lower power line disposed below the first semiconductor pattern;
a second lower power line disposed below the second semiconductor pattern; and
a third lower power line disposed below the third semiconductor pattern,
wherein a value of the first power voltage and a value of the second power voltage are each different from a value of the third power voltage, and
wherein at least one of the first lower power line, the second lower power line, and the third lower power line is electrically connected to a corresponding power line among the first power line, the second power line, and the third power line.

2. The display device of claim 1, wherein the first power line and the second power line are electrically connected to each other and separated from the third power line.

3. The display device of claim 1, wherein the first lower power line and the second lower power line are electrically connected to each other and separated from the third lower power line.

4. The display device of claim 3, wherein
the first lower power line or the second lower power line is electrically connected to a corresponding power line among the first power line and the second power line, and
any one of the first lower power line and the second lower power line is separated from the corresponding power line among the first power line and the second power line.

5. The display device of claim 3, further comprising
a display area including the first subpixel circuit, the second subpixel circuit, and the third subpixel circuit, and
a peripheral area proximate to the display area,
wherein the first lower power line and the second lower power line each extend to the peripheral area.

6. The display device of claim 5, wherein
the first lower power line and the second lower power line are electrically connected to a power voltage line disposed in the peripheral area, the first lower power line and the second lower power line configured to receive the first power voltage or the second power voltage, and
wherein the third lower power line is electrically connected to the third power line, and the third lower power line is configured to receive the third power voltage.

7. The display device of claim 1, wherein the first lower power line and the second lower power line are integrally formed with one another, and
wherein the first lower power line and the second lower power line together have a mesh structure.

8. The display device of claim 7, wherein the third lower power line has an island shape disposed in an opening of the mesh structure.

9. The display device of claim 8, wherein the island shape of the third lower power line includes protrusions extending toward the first lower power line or the second lower power line.

10. The display device of claim 1, wherein the value of the first power voltage is equal to the value of the second power voltage.

11. A display device, comprising:
a first subpixel comprising a first semiconductor pattern, a first power line disposed on the first semiconductor pattern, and a first lower power line disposed below the first semiconductor pattern;
a second subpixel comprising a second semiconductor pattern, a second power line disposed on the second semiconductor pattern, and a second lower power line disposed below the second semiconductor pattern; and
a third subpixel comprising a third semiconductor pattern, a third power line disposed on the third semiconductor pattern, and a third lower power line disposed below the third semiconductor pattern,
wherein the third lower power line is separated from both the first lower power line and the second lower power line and electrically connected to the third power line.

12. The display device of claim 11, wherein the first lower power line and the second lower power line are electrically connected to each other.

13. The display device of claim 12, wherein the first lower power line and the second lower power line are electrically connected to at least one of the first power line and the second power line.

14. The display device of claim 12, further comprising:
a display area including the first subpixel, the second subpixel, and the third subpixel, and
a peripheral area proximate to the display area,
wherein the first lower power line and the second lower power line each extend to the peripheral area.

15. The display device of claim 14, wherein the first lower power line and the second lower power line are electrically connected to a power voltage line disposed in the peripheral area.

16. The display device of claim 11, wherein the first lower power line and the second lower power line are integrally formed with one another, and
wherein the first lower power line and the second lower power line together have a mesh structure.

17. The display device of claim 16, wherein the third lower power line has an island shape disposed in an opening of the mesh structure.

18. The display device of claim 17, wherein the island shape of the third lower power line includes protrusions extending toward the first lower power line or the second lower power line.

19. The display device of claim 11, wherein a first power voltage is applied to the first power line, a second power voltage having an equal value as the first power voltage is applied to the second power line, and a third power voltage having a different value from the first power voltage is applied to the third power line.

20. An electronic device comprising a housing and a display device disposed inside the housing, wherein the display device comprises:
a first subpixel circuit comprising a first thin-film transistor, the first thin-film transistor comprising a first semiconductor pattern;
a second subpixel circuit comprising a second thin-film transistor, the second thin-film transistor comprising a second semiconductor pattern;
a third subpixel circuit comprising a third thin-film transistor, the third thin-film transistor comprising a third semiconductor pattern;
a first power line disposed on the first semiconductor pattern, the first power line configured to apply a first power voltage to the first subpixel circuit;
a second power line disposed on the second semiconductor pattern, the second power line configured to apply a second power voltage to the second subpixel circuit;
a third power line disposed on the third semiconductor pattern, the third power line configured to apply a third power voltage to the third subpixel circuit;
a first lower power line disposed below the first semiconductor pattern;
a second lower power line disposed below the second semiconductor pattern; and
a third lower power line disposed below the third semiconductor pattern,
wherein a value of the first power voltage and a value of the second power voltage are each different from a value of the third power voltage, and
wherein at least one of the first lower power line, the second lower power line, and the third lower power line is electrically connected to a corresponding power line among the first power line, the second power line, and the third power line.
